(19) United States
(12) Patent Application Publication
(10) Pub. No.: US 2025/0338453 A1
(43) Pub. Date: Oct. 30, 2025

(54) SERVERS, SYSTEMS, AND METHODS FOR CONTROLLING FLUID LEVELS IN AN IMMERSION COOLING RACK IN RESPONSE TO A CHANGE IN FLUID DISPLACING EQUIPMENT

(71) Applicant: Green Revolution Cooling, Inc., Austin, TX (US)

(72) Inventor: John H. Bean, JR., Littlestown, PA (US)

(21) Appl. No.: 19/195,081

(22) Filed: Apr. 30, 2025

Related U.S. Application Data
(60) Provisional application No. 63/640,793, filed on Apr. 30, 2024.

(51) Int. Cl. H05K 7/20

(52) U.S. Cl. CPC H05K 7/20772

(57) ABSTRACT

The disclosure is directed to a system for managing fluid levels in liquid immersion cooling racks during the addition and/or removal of fluid displacing equipment. In some embodiments, the system is configured to determine expected fluid level changes based on the volume of fluid displacing equipment and a current fluid level of cooling tanks and/or reservoirs. Control commands are generated to actuate valves and pumps, ensuring fluid levels remain within operating setpoints to maintain coverage of remaining components and prevent overflow, in accordance with some embodiments. In some embodiments, temperature data is analyzed to evaluate the impact of fluid transfer on thermal requirements. In some embodiments, actual measurements from operations are stored to refine predictive models for future adjustments. In some embodiments, the system redistributes fluid. In some embodiments, program instructions automate fluid transfer operations among multiple immersion cooling racks simultaneously, ensuring consistent cooling performance across interconnected racks and reservoirs. In some embodiments an operator may be prompted to enter the quantity and models of heat producing equipment to be added or removed from the racks, the system may evaluate the various stores of fluid in the racks and reservoirs to determine whether the existing fluid stores, combined with intended additions and or deletions of heat producing equipment may be accommodated within the allowable limits of the system without need for ancillary addition or removal of fluid.

### CROSS REFERENCE TO RELATED APPLICATION

This application claims the benefit and priority of U.S. Provisional Patent Application No. 63/640,793 filed Apr. 20, 2024, the disclosure of which is incorporated by reference herein in its entirety.

### FIELD OF THE DISCLOSURE

The present disclosure is generally related to immersion cooling systems. More particularly, some embodiments are related to a framework for controlling a level in a cooling tank of an immersion cooling rack when fluid displacing equipment is added or removed.

### BACKGROUND

The management of fluid levels in immersion cooling systems presents unique challenges due to the dynamic nature of fluid displacement caused by the addition or removal of electronic components as well as expansion and contraction of fluid volume due to temperature changes of the fluid. Immersion cooling systems rely on dielectric coolant fluids to regulate the temperature of heat-producing equipment, such as servers, processors, and other electronic components, which are at least partially submerged in the coolant. Changes in the configuration of these systems, such as the removal or addition of fluid displacing equipment, can result in significant fluctuations in fluid levels, potentially leading to insufficient coverage of components or overflow conditions. These fluctuations can compromise the thermal management of the system, leading to equipment failure or reduced operational efficiency.

Traditional approaches to fluid level management often rely on manual adjustments or static configurations, which are insufficient to address the dynamic and complex requirements of modern immersion cooling platforms. Factors such as thermal expansion or contraction of the coolant, variations in component geometry, and differences in heat generation across multiple racks further complicate the management of fluid levels. Additionally, the need to maintain consistent cooling across multiple racks sharing a unified coolant distribution system introduces additional challenges in ensuring balanced fluid distribution and preventing localized overheating or undercooling.

### SUMMARY OF THE DISCLOSURE

Some embodiments of the disclosure are directed to a system configured to manage fluid levels in liquid immersion cooling racks when fluid displacing equipment is added and/or removed. In some embodiments, the system uses a volume of the equipment being added/removed to determine a resulting fluid level change within a cooling tank. In some embodiments, sensors retrieve data to assess the current state of a cooling tank and/or reservoir and the system determines an amount of fluid to add or remove (also referred to as “delete” herein) to maintain desired coverage of remaining components. In some embodiments, the system generates/executes control commands to actuate system components to enable delivery of fluid to/from the cooling to ensure fluid levels remain within operating setpoints. In some embodiments, temperature data is analyzed to assess the impact of fluid transfer and/or expected level change on thermal requirements. In some embodiments, the system stores actual level change measurements from add/delete operations to refine predictive models for future additions and/or removals.

In some embodiments, the system is configured to redistribute fluid among multiple immersion cooling racks simultaneously to maintain fluid levels and/or redistribute fluid due to equipment addition and/or deletion. In some embodiments, the system is configured to monitor fluid levels across a plurality of liquid cooling immersion racks and determine the volume required for transfer to maintain setpoint levels in each cooling rack. In some embodiments, the system is configured to automatically actuate valves and pumps to redistribute fluid to different racks and/or reservoirs in response to expected level changes. In some embodiments, the system is configured to use one or more reservoirs to hold excess coolant from the cooling tanks and assist in managing fluid levels.

In some embodiments, the system comprises one or more computers comprising one or more processors and one or more non-transitory computer readable media, the one or more non-transitory computer readable media comprising program instructions stored thereon that when executed cause the one or more computers to execute one or more program instruction steps. Some embodiments include a step to receive, by the one or more processors, level data from one or more sensors associated with a liquid immersion cooling rack. Some embodiments include a step to determine, by the one or more processors, an expected change in a level of a cooling tank associated with the immersion cooling rack as a result of one or more fluid displacing components being added and/or removed from the cooling tank. Some embodiments include a step to execute, by the one or more processors, a fluid transfer operation configured to prevent the level in the cooling tank from dropping below and/or rising above a pre-determined setpoint.

In some embodiments, the expected change in the level of the cooling tank is at least partially determined using a tank volume of fluid in the cooling tank and a component volume of the one or more fluid displacing components. In some embodiments, the expected change in the level of the cooling tank is at least partially determined by using a temperature of the cooling. In some embodiments, the expected change in the level of the cooling tank is at least partially determined by determining a change in cooling tank temperature caused by a removal and/or addition of the one or more fluid displacing components.

In some embodiments, the fluid transfer operation includes automatic control of one or more valves to deliver additional fluid to the cooling tank and/or remove fluid from the cooling tank. In some embodiments, the additional fluid is configured to prevent one or more remaining components from becoming exposed to atmosphere. In some embodiments, removing the fluid is helps prevent the cooling tank from overflowing.

In some embodiments, the fluid transfer operation includes transferring liquid from one or more other immersion cooling racks to the cooling tank. In some embodiments, the fluid transfer operation includes transferring liquid to and/or from a reservoir to the cooling tank. In some embodiments, the fluid transfer operation includes transferring liquid to the cooling tank from a fluid circuit. In some embodiments, the fluid circuit includes a plurality of immersion cooling racks and a plurality of coolant distribution units.

### DESCRIPTIONS OF THE DRAWINGS

The features, and advantages of the disclosure will be apparent from the following description of embodiments as illustrated in the accompanying drawings, in which reference characters refer to the same parts throughout the various views. The drawings are not necessarily to scale, emphasis instead being placed upon illustrating principles of the disclosure:

FIG. 1 illustrates a block diagram of an example configuration within which the systems and methods disclosed herein could be implemented, in accordance with some embodiments of the present disclosure;

FIG. 2 shows a block diagram illustrating components of an exemplary system, in accordance with some embodiments of the present disclosure;

FIG. 3 illustrates an example configuration workflow, in accordance with some embodiments of the present disclosure;

FIG. 4 illustrates an example execution workflow, in accordance with some embodiments of the present disclosure;

FIG. 5 depicts an example implementation of an architecture, in accordance with some embodiments of the present disclosure;

FIG. 6 depicts an example implementation of an architecture, in accordance with some embodiments of the present disclosure;

FIG. 7 illustrates a block diagram illustrating a computing device showing an example of a client or server device, in accordance with some embodiments of the present disclosure;

FIG. 8 illustrates a non-limiting example immersion cooling rack within an immersion cooling platform, in accordance with some embodiments;

FIG. 9 illustrates a portion of the cooling infrastructure of the immersion cooling system, in accordance with some embodiments;

FIGS. 10A-10D illustrate examples of various aspects of a multi-rack cooling system, in accordance with some embodiments of the present disclosure;

FIG. 11A shows a perspective cut-away view of a rear side of an immersion cooling rack, in accordance with some embodiments of the present disclosure;

FIG. 11B depicts a relief view of one side of the immersion cooling rack of FIG. 2A, in accordance with some embodiments of the present disclosure;

FIG. 11C shows a relief view of one side of the immersion cooling rack of FIGS. 2A and 2B with coolant flowing therein, in accordance with some embodiments of the present disclosure;

FIG. 12A illustrates a vertical cross-sectional cut-away view of an immersion cooling rack showing various features of various embodiments, in accordance with some embodiments of the present disclosure;

FIG. 12B shows a vertical cross-sectional cut-away view of an immersion cooling rack with an adjustable height weir, in accordance with some embodiments of the present disclosure;

FIG. 13 depicts a perspective view of an immersion cooling rack with side-walls removed to reveal an inner portion of a main cooling tank, in accordance with some embodiments of the present disclosure;

FIG. 14 depicts a perspective view of a front side of an immersion cooling rack with upper components removed to better show a weir used between the main and buffer cooling tanks and flow of coolant, in accordance with some embodiments of the present disclosure;

FIGS. 15A-15B illustrate side cross-sectional views of adjacent pairs of immersion cooling racks with and without one-way valves, in accordance with some embodiments of the present disclosure;

FIG. 16A shows a right-side perspective view of an immersion cooling rack assembly with a video monitor, in accordance with some embodiments of the present disclosure;

FIG. 16B illustrates a front view of an immersion cooling rack assembly with a video monitor, in accordance with some embodiments of the present disclosure;

FIG. 16C depicts a left side perspective view of an immersion cooling rack assembly with a video monitor, in accordance with some embodiments of the present disclosure;

FIG. 17A is a schematic view of a single-phase cooling distribution unit used to cool two component cooling tanks in accordance with various embodiments.

FIG. 17B is a schematic view of a single-phase cooling distribution unit used to cool four component cooling tanks in accordance with various embodiments.

FIG. 18A is a perspective view of a system schematic for controlling coolant levels in component cooling tanks sharing a unified coolant distribution system in accordance with various embodiments.

FIG. 18B is a schematic relief view of a coolant level detector suitable for use with various embodiments.

FIGS. 19A and 19B are vertical cross-sectional views of a component cooling tank including a reservoir with a coolant release valve in closed and open positions, respectively, in accordance with various embodiments.

FIG. 20A is a perspective relief view of a linear coolant release valve in a reservoir in accordance with various embodiments.

FIG. 20B is a perspective relief view of a rotary coolant release valve in a reservoir in accordance with various embodiments.

FIG. 21 is a process flow diagram of a method for controlling coolant levels in two or more component cooling tanks sharing a unified coolant distribution system in accordance with various embodiments.

### DETAILED DESCRIPTION

The present disclosure will now be described more fully hereinafter with reference to the accompanying drawings, which form a part hereof, and which show, by way of non-limiting illustration, certain example configurations, in accordance with some embodiments. Subject matter may, however, be embodied in a variety of different forms, as well as combinations of features depicted in non-limiting configurations. Therefore, covered or claimed subject matter is intended to be construed as not being limited to any example configuration of structures or function set forth herein. Example configurations, which borrow from portions of the system, are provided merely to show how one of ordinary skill could make and use the system using some embodiments of the present disclosure. Likewise, a broad scope for claimed or covered subject matter is intended.

Throughout the specification and claims, terms may have nuanced meanings suggested or implied in context beyond an explicitly stated meaning. Likewise, the phrase “in some embodiments” as used herein does not necessarily refer to the same embodiment and the phrase “in some embodiments” as used herein does not necessarily refer to a different embodiment. It is intended, for example, that claimed subject matter includes combinations of any embodiments, in whole or in part, described herein.

In some embodiments, the system includes one or more immersion cooling racks. In some embodiments, each immersion cooling rack includes a component cooling tank, a buffer cooling tank, and/or a reservoir. In some embodiments, the component cooling tank is configured to hold one or more fluid displacing electronic equipment/components (used interchangeably herein) at least partially submerged in a dielectric coolant liquid. In some embodiments, the buffer cooling tank which may also serve as a reservoir is fluidly coupled to the component cooling tank via one or more weirs.

In some embodiments, a rack includes structural equipment configured to contain and support coolant flow and thermal management subsystems. In some embodiments, the structural equipment includes a frame, one or more removable outer panels, and/or a removable upper panel that includes and/or supports user equipment (UE) 102, such as a client device. In some embodiments, the rack includes fluid interface components for ingress and egress of coolant. In some embodiments, the inlet and/or outlet duct includes a valve configured to isolate the rack from a cooling circuit.

In some embodiments, the rack includes one or more sensors. In some embodiments, the sensors include temperature sensors disposed in the component cooling tank and/or in the buffer tank. In some embodiments, the sensors include a coolant fluid level sensor and/or a fluid level detection sensor. In some embodiments, the rack includes a thermal switch that is triggered when the coolant fluid temperature crosses a threshold and is configured to restrict or allow coolant flow through one or more adjustable valves.

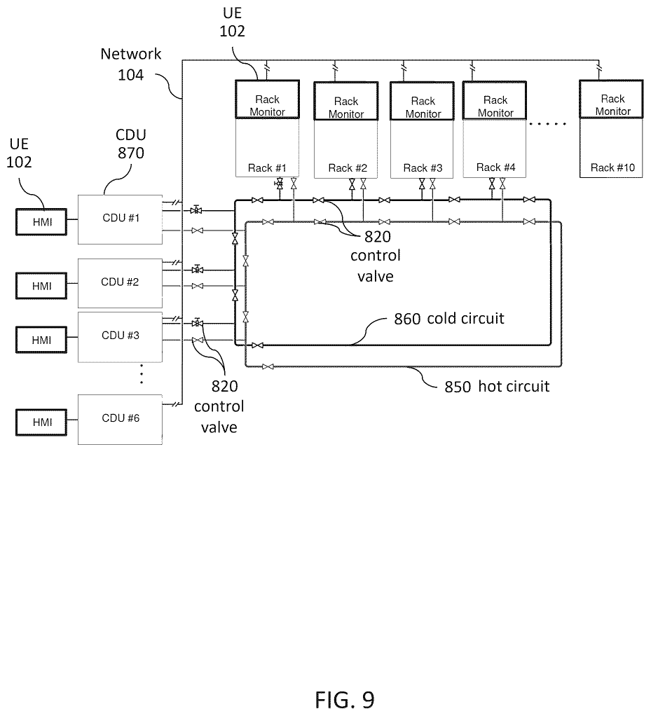

In some embodiments, the system is configured to use the rack as part of a multi-rack arrangement, as discussed in relation to FIG. 9 below. In some embodiments, the multi-rack system includes two or more racks fluidly coupled to a cooling circuit and one or more coolant distribution units (CDUs). In some embodiments, the cooling circuit includes multiple inlet and outlet ducts corresponding to each rack. In some embodiments, each rack operates independently with respect to temperature and load but shares one or more coolant sources.

In some embodiments, the fluid displacing components displace volume within the component cooling tank during steady state or other operational states. In some embodiments, the volume displacement is a function of the physical geometry and positioning of the components submerged in the coolant. In some embodiments, fluid displacing components include electronic components such as servers, central processing units (CPUs), server blades, printed circuit boards, processors, memory modules, wiring, support frames, and/or power distribution units, as non-limiting examples.

In some embodiments, the system is configured to enable a user to enter a volume of a fluid displacing component into a database. In some embodiments, the system is configured to determine a displacement volume from by measuring a change in fluid level before and after a component removal. While this can be done at steady state, in some embodiments, a method step includes measuring fluid displacement in a displacement measuring container using the previously mentioned process. A database of displacement volumes from various components may be formed from system executed determinations, in accordance with some embodiments.

In some embodiments, a rack includes serviceable and/or removable fluid displacing equipment, such as hot-swappable drives, blade assemblies, and/or removable compute modules, as non-limiting examples. In some embodiments, such modules can be inserted or removed during maintenance, upgrade, and/or reconfiguration events while other components are still operating and/or producing heat in the cooling tank. In some embodiments, the removal of these components creates a net increase in available fluid volume within the component cooling tank, which corresponds to a drop in fluid level.

In some embodiments, the fluid/volume displacing equipment includes non-electronic structures such as cable management brackets, sensor housings, support rails, subframes, structural ribs, and/or ballast elements. In some embodiments, these components are affixed within the tank, where the displacement caused by these components is stored in a database as fixed. In some embodiments, these components are stored in a database as being able to be removed, such as for maintenance and/or upgrade. In some embodiments, the difference in volume between old and new components can be used to configure the system to automatically adjust fluid levels and/or fluid exchange rates for the new components, as opposed to waiting for the system to respond to sensors detecting a level change. In some embodiments, the system is configured to raise and/or lower the cooling tank level within a system determined range that enables one or more fluid displacing components to remain covered when a component is removed, while preventing and/or controlling overflow when a new fluid displacing component is added.

In some embodiments, the displacement of volume by installed components creates a stable baseline for coolant fluid level in the component cooling tank. In some embodiments, the removal of volume-displacing components, such as electronic modules or support elements, causes the level of coolant fluid to decrease. In some embodiments, the system is configured to initiate a refill or flow adjustment operation in response to volume-related level changes.

In some embodiments, the disclosed system provides a comprehensive solution for managing fluid levels in immersion cooling racks and tanks, addressing challenges such as fluid displacement due to the addition or removal of fluid displacing components, and/or thermal expansion or contraction of the cooling fluid. In some embodiments, the system automates the transfer of fluid between reservoirs and racks to maintain optimal fluid levels, preventing overflow or insufficient coverage of fluid displacing equipment (e.g., servers, power supplies, wiring), which could lead to equipment failure. Some embodiments are configured to monitor temperature and/or temperature changes, enabling compensation of volumetric changes due to fluid density variations.

In some embodiments, when operating at steady state (i.e., no change in fluid displacing equipment), the system is configured to evaluate fluid levels and redistribute excess fluid through various monitoring and fluid control execution techniques described herein. In some embodiments, in an add state, the system is configured to automatically determine and/or adjust fluid levels to accommodate newly immersed fluid displacing equipment. In some embodiments, while in a remove state, the system is configured to automatically determine and/or execute fluid level changes due to fluid displacing component removal. In some embodiments, the system is configured to enable a user to configure a cooling tank for a particular state, where in some embodiments, the system is configured to automatically determine a state due to one or more of disconnection of equipment, a rise in fluid level, and a drop in fluid level.

In some embodiments, utilizing a shared fluid loop, the system controls distribution among a plurality of racks, allowing fluid to be redistributed among one or more racks as needed, ensuring consistent cooling across all racks (see FIG. 9). In some embodiments, the system is configured to monitor fluid levels in a plurality of cooling tanks and/or communicate with other cooling tanks platforms to manage fluid distribution effectively.

In some embodiments, one or more racks include one or more fluid level sensors that monitor the fluid levels within the cooling tank and/or the reservoir tank, providing monitoring data to maintain optimal fluid levels. In some embodiments, temperature sensors measure the temperature of the cooling fluid, allowing the system to adjust fluid levels based on thermal expansion or contraction. In some embodiments, controllers are integrated into the rack to process data from these sensors and execute control commands to manage fluid distribution and temperature regulation, as further discussed herein.

In some embodiments, one or more racks and/or reservoir include one or more pumps and/or venturis to facilitate the movement of fluid between a cooling tank and a reservoir tank, and/or between different racks. In some embodiments, communication interfaces are provided to enable interaction between different racks and/or reservoirs, allowing them to coordinate fluid distribution and maintain consistent cooling across the system. In some embodiments, the system is configured to control valves to regulate the flow of fluid between one or more racks, one or more reservoirs, and/or within a shared fluid loop.

In some embodiments, one or more racks include cooling infrastructure, such as heat exchangers (e.g., CDUs), to remove heat from the cooling fluid. In some embodiments, one or more racks are equipped with controllers that monitor fluid levels and/or communicate with other racks to manage fluid distribution effectively. In some embodiments, the system can issue requests to other racks to add or remove fluid based on current needs. In some embodiments, the system may use a fluid transfer device, such as a venturi or pump to facilitate fluid transfer between the cooling tank and the reservoir tank, ensuring efficient fluid movement (see FIG. 9).

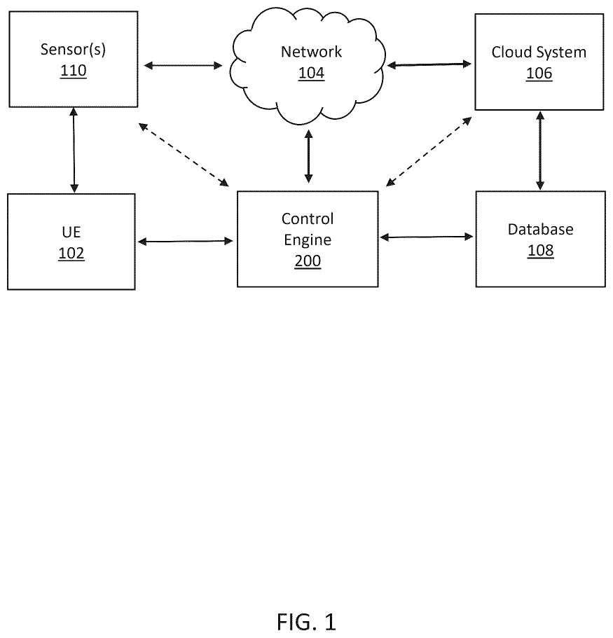

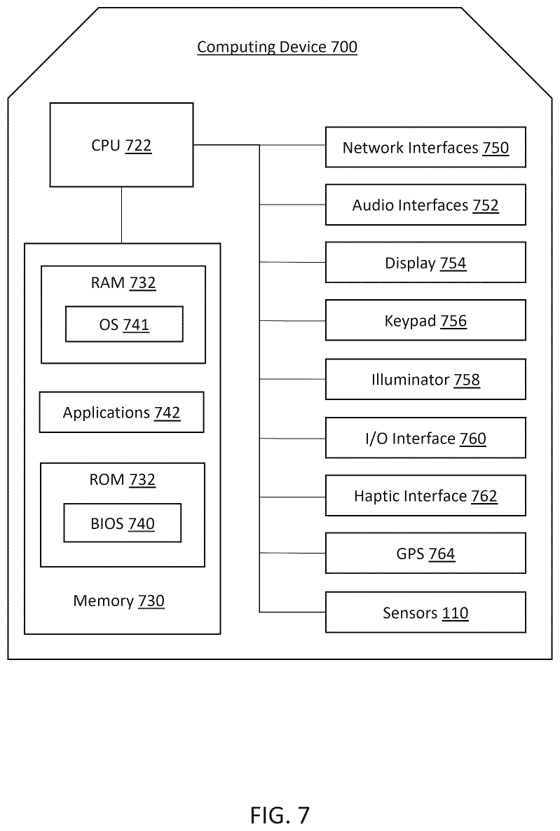

With reference to FIG. 1, system 100 is depicted which includes user equipment (UE) 102 (e.g., a client device, as mentioned above and discussed below in relation to FIG. 7), network 104, cloud platform 106, database 108 and control engine 200. It should be understood that while system 100 is depicted as including such components, it should not be construed as limiting, as one of ordinary skill in the art would readily understand that varying numbers of UEs, peripheral devices, cloud platforms, databases and networks can be utilized; however, for purposes of explanation, system 100 is discussed in relation to the example depiction in FIG. 1.

According to some embodiments, UE 102 can be any type of device, such as, but not limited to, and HMI, a desktop computer, a server, a mobile (smart) phone, tablet, laptop, sensor, IoT device, autonomous machine, appliance, and/or any device equipped with a wireless and/or wired transceiver. For example, UE 102 can be a controller, which, as discussed below in more detail, can enable the monitoring and control of fluid levels in immersion cooling systems, allowing users to issue commands and collect system status information.

In some embodiments, one or more peripheral devices (not shown) can be connected to UE 102, and can be any type of peripheral device, such as, but not limited to, a wearable device, printer, speaker, sensor, and the like. In some embodiments, a peripheral device can be any type of device that is connectable to UE 102 via any type of known or to be known pairing mechanism, including, but not limited to, Wi-Fi, Bluetooth™, Bluetooth Low Energy (BLE), Near-Field Communication (NFC), and the like. For example, the peripheral device can be a camera that connectively pairs with UE 102 to provide additional data for monitoring and controlling fluid levels in immersion cooling systems.

In some embodiments, network 104 can be any type of network, such as, but not limited to, a wireless network, cellular network, the Internet, and the like (as discussed above). Network 104 enables connectivity of the components of system 100, as illustrated in FIG. 1.

According to some embodiments, cloud platform 106 may be any type of cloud operating platform and/or network-based system upon which applications, operations, and/or other forms of network resources may be located. For example, cloud platform 106 may be a service provider and/or network provider from where services and/or applications may be accessed, sourced, or executed from. For example, platform 106 can represent the cloud-based architecture associated with a smart home or network provider, which has associated network resources hosted on the internet or private network (e.g., network 104), which enables (via control engine 200) the device control and management discussed herein.

In some embodiments, cloud platform 106 may include a server(s) and/or a database of information which is accessible over network 104. In some embodiments, a database 108 of cloud platform 106 may store a dataset of data and metadata associated with local and/or network information related to system 100 and/or fluid displacing components of system 100. In some embodiments, for example, cloud platform 106 can provide a private/proprietary management platform, whereby control engine 200, discussed infra, corresponds to the novel functionality platform 106 enables, hosts, and provides to a network 104 and other devices/platforms operating thereon.

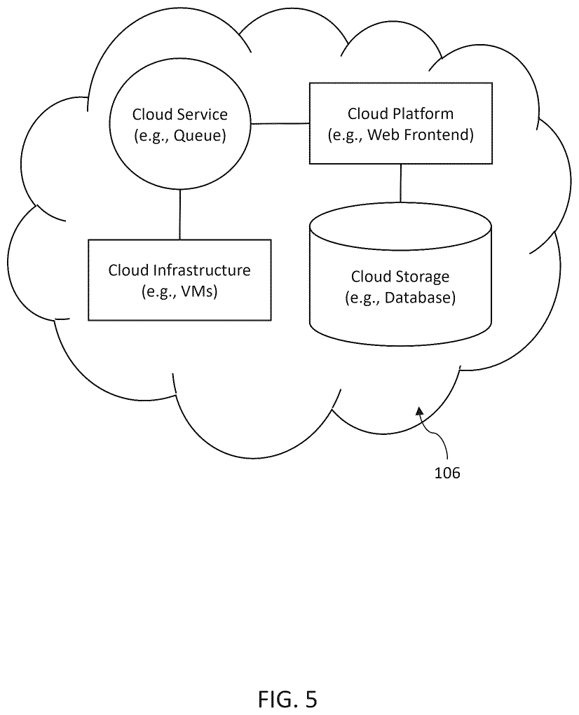

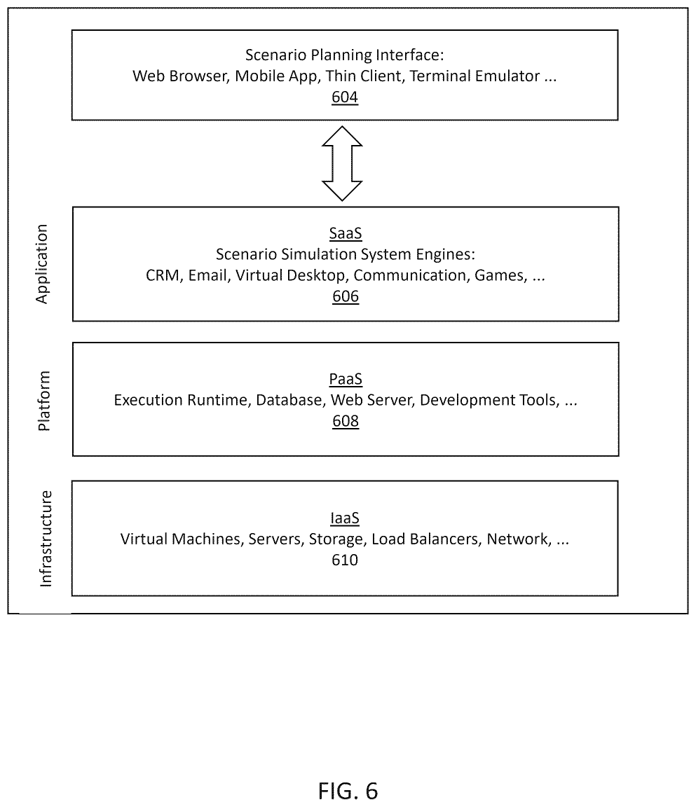

Turning now to FIGS. 5 and 6, in some embodiments, the exemplary computer-based systems/platforms, the exemplary computer-based devices, and/or the exemplary computer-based components of the present disclosure may be specifically configured to operate in a cloud computing/architecture 106 such as, but not limiting to: infrastructure as a service (IaaS) 610, platform as a service (PaaS) 608, and/or software as a service (SaaS) 606 using a web browser, mobile app, thin client, terminal emulator or other endpoint 604. FIGS. 5 and 6 illustrate schematics of non-limiting implementations of the cloud computing/architecture(s) in which the exemplary computer-based systems for administrative customizations and control of network-hosted application program interfaces (APIs) of the present disclosure may be specifically configured to operate.

Turning back to FIG. 1, according to some embodiments, database 108 may include data storage for a platform (e.g., a network hosted platform, such as cloud platform 106, as discussed supra) or a plurality of platforms. In some embodiments, database 108 may receive storage instructions/requests from, for example, control engine 200 (and associated microservices), which may be in any type of known or to be known format, such as, for example, standard query language (SQL). According to some embodiments, database 108 may correspond to any type of known or to be known storage, for example, a memory or memory stack of a device, a distributed ledger of a distributed network (e.g., blockchain, for example), a look-up table (LUT), and/or any other type of secure data repository, including the servers which the system is implemented to protect.

For the purposes of this disclosure a non-transitory computer readable medium (or computer-readable storage medium/media) stores computer data, which data can include computer program code (or computer-executable/implementable instructions) that is executable by a computer, in machine readable form. By way of example, and not limitation, a computer readable medium may include one or more non-transitory computer readable storage media, for tangible or fixed storage of data, or communication media for transient interpretation of code-containing signals. Computer readable storage media, as used herein, refers to physical or tangible storage (as opposed to signals) and includes without limitation volatile and non-volatile, removable, and non-removable media implemented in any method or technology for the tangible storage of information such as computer-readable instructions, data structures, program modules or other data. Computer readable storage media includes, but is not limited to, RAM, ROM, EPROM, EEPROM, flash memory or other solid state memory technology, optical storage, cloud storage, magnetic storage devices, or any other physical or material medium which can be used to tangibly store the desired information or data or instructions and which can be accessed by a computer or processor.

For the purposes of this disclosure the term “server” should be understood to refer to a service point which provides processing, database, and communication facilities. By way of example, and not limitation, the term “server” can refer to a single, physical processor with associated communications and data storage and database facilities, or it can refer to a networked or clustered complex of processors and associated network and storage devices, as well as operating software and one or more database systems and application software that support the services provided by the server. Cloud servers are examples.

For the purposes of this disclosure a “network” should be understood to refer to a network that may couple devices so that communications may be exchanged, such as between a server and a client device or other types of devices, including between wireless devices coupled via a wireless network, for example. A network may also include mass storage, such as network attached storage (NAS), a storage area network (SAN), a content delivery network (CDN) or other forms of computer or machine-readable media, for example. A network may include the Internet, one or more local area networks (LANs), one or more wide area networks (WANs), wire-line type connections, wireless type connections, cellular or any combination thereof. Likewise, sub-networks, which may employ differing architectures or may be compliant or compatible with differing protocols, may interoperate within a larger network. Various features of the control framework described herein uses one or more networks to transmit data and/or implement instructions.

For purposes of this disclosure, a “wireless network” should be understood to couple client devices with a network. A wireless network may employ stand-alone ad-hoc networks, mesh networks, Wireless LAN (WLAN) networks, cellular networks, or the like. A wireless network may further employ a plurality of network access technologies, including Wi-Fi, Long Term Evolution (LTE), WLAN, Wireless Router mesh, or 2nd, 3rd, 4^{th}, or 5^{th} generation (2G, 3G, 4G or 5G) cellular technology, mobile edge computing (MEC), Bluetooth®, 802.11b/g/n, or the like. Network access technologies may enable wide area coverage for devices, such as client devices with varying degrees of mobility, for example. In short, a wireless network may include virtually any type of wireless communication mechanism by which signals may be communicated between devices, such as a client device (e.g., the controller computing device(s) described herein), between or within a network, or the like.

A computing device, which may include one or more computers, may be capable of sending or receiving signals, such as via a wired or wireless network, or may be capable of processing or storing signals, such as in memory as physical memory states, and may, therefore, operate as a server. Thus, devices capable of operating as a server may include, as examples, dedicated rack-mounted servers, desktop computers, laptop computers, set top boxes, integrated devices combining various features, such as two or more features of the foregoing devices, or the like.

For purposes of this disclosure, a client device (e.g., UE 102) may include a computing device capable of sending or receiving signals, such as via a wired or a wireless network. A client device may, for example, include a desktop computer or a portable device, such as a cellular telephone, a smart phone, a display pager, a radio frequency (RF) device, an infrared (IR) device a Near Field Communication (NFC) device, a Personal Digital Assistant (PDA), a handheld computer, a tablet computer, a phablet, a laptop computer, a set top box, a wearable computer, smart watch, an integrated or distributed device combining various features, such as features of the forgoing devices, or the like.

A client device may vary in terms of capabilities or features. For example, a client device may include one or more controllers configured to execute any of the instructions described herein: it should be understood that instructions associated with a particular configuration are not limited to that configuration, and that the system includes all computer implemented instructions described herein alone, in part, and/or in combination with other instructions in accordance with some embodiments. Claimed subject matter is intended to cover a wide range of potential variations.

The system may include one or more web-enabled client devices that may, for example, include a high-resolution screen (e.g., HD or 4K), one or more physical or virtual keyboards, mass storage, one or more accelerometers, one or more gyroscopes, global positioning system (GPS) or other location-identifying type capability, or a display with a high degree of functionality, such as a touch-sensitive color 2D or 3D display, for example, that enable a user to visualize and/or implement the instructions.

Control engine 200, as discussed above and further below in more detail, can include components for the disclosed functionality. According to some embodiments, at least part of control engine 200 may be a special purpose machine or processor and can be hosted, at least in part by a device on network 104, within cloud platform 106, and/or on UE 102. In some embodiments, at least part of control engine 200 may be hosted by a server and/or set of servers associated with cloud platform 106 and/or one or more immersion cooling racks described herein.

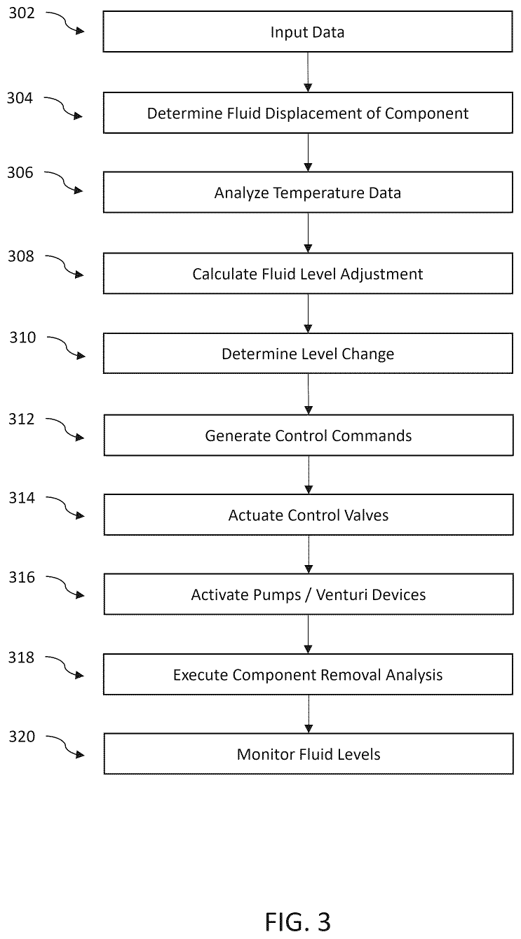

According to some embodiments, as discussed in more detail below, control engine 200 may be configured to implement and/or control a plurality of services and/or microservices, where each of the plurality of services/microservices are configured to execute a plurality of workflows associated with performing the disclosed application control and management framework. Non-limiting embodiments of such workflows are provided below in relation to at least FIGS. 3, 4, and 21.

According to some embodiments, as discussed above, at least part of control engine 200 may function as an application provided by cloud platform 106. In some embodiments, at least part of control engine 200 may function as an application installed on a server(s), network location and/or other type of network resource associated with platform 106. In some embodiments, at least part of control engine 200 may function as application installed and/or executing on UE 102. In some embodiments, such application may be a web-based application accessed by UE 102 over network 104 from cloud platform 106. In some embodiments, at least part of control engine 200 may be configured and/or installed as an augmenting script, program, or application (e.g., a plug-in or extension) to another application or program provided by cloud platform 106 and/or executing on UE 102.

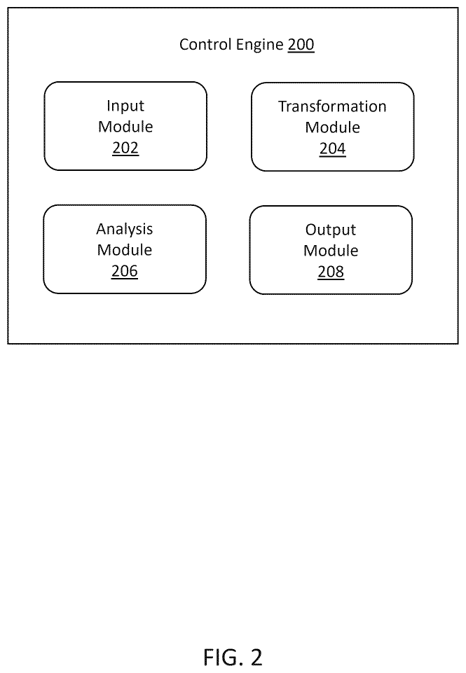

As illustrated in FIG. 2, according to some embodiments, control engine 200 includes one or more of an input module 202, a transformation module 204, an analysis module 206, and an output module 208. It should be understood that the engine(s) and modules discussed herein are non-exhaustive, as additional, or fewer engines and/or modules (or sub-modules) may be applicable to the embodiments of the systems and methods discussed. The recitation of the module framework may be omitted when defining the metes and bounds of the system, as source of the execution of the algorithmic steps are not limited to any particular program architecture. More detail of the operations, configurations, and functionalities of control engine 200 and each of its modules, and their role within embodiments of the present disclosure will be discussed below.

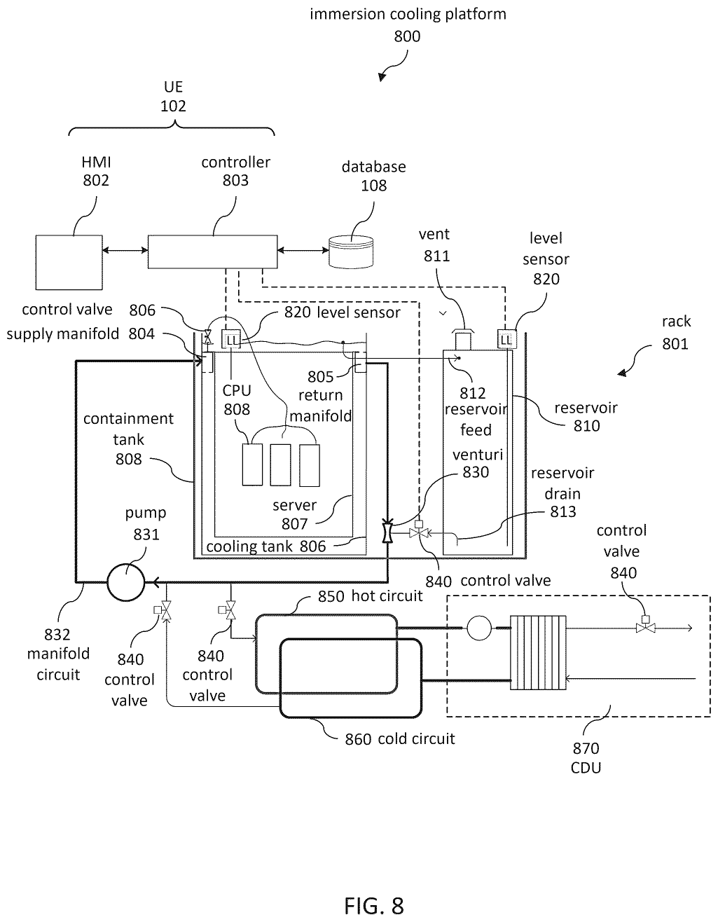

FIG. 8 illustrates a non-limiting example immersion cooling rack 801 within an immersion cooling platform, in accordance with some embodiments. In some embodiments, a human-machine interface (HMI) 802 is configured to enable a user to input data, such as fluid displacement volume and setpoints, for monitoring and controlling the system and receiving feedback on system status. In some embodiments, controller 803 is configured to process data and execute control commands from control engine 200, receiving input from one or more sensors, such as level sensors 808, and/or other sensors 110 to adjust fluid levels and maintain optimal cooling conditions. In some embodiments, database 108 stores data related to the system's operation, including fluid levels, temperature readings, component/equipment displacement volume, and/or user commands. While an HMI 802 and controller 803 are described in relation to this non-limiting example, any user equipment 102 configuration described herein may be used to execute program instructions associated with the system.

In some embodiments, the rack 801 includes a manifold circuit 832. In some embodiments, the manifold circuit 832 includes one or more fluid conduits that form a supply manifold 804 and a return manifold 805. In some embodiments, supply manifold 804 is configured to distribute cooling liquid to various parts of the system, ensuring that the cooling liquid is evenly distributed across the rack 801 to maintain fluid level setpoints. In some embodiments, one or more control valves 805 are configured to regulate the flow of fluid within the system. In some embodiments, the actuation of one or more control valves 805 is implemented by control engine 200, via controller 803, for example, controlling the movement of fluid between the cooling tank 816 and/or the reservoir 810 to prevent overflow, control temperature, and/or prevent insufficient coverage of one or more servers 809 and/or one or more central processing units (CPUs) 817. In some embodiments, the return manifold 805 is configured to collect and direct the cooling fluid back to the cooling tank 816 after the cooling fluid has circulated through the hot circuit 850 and/or cold circuit 860.

In some embodiments, reservoir 810 serves as an auxiliary tank for storing excess cooling fluid for rack 801, assisting in managing fluid levels by receiving overflow from the cooling tank 816 from reservoir feed 812 (e.g., gravity drain conduit from cooling tank 806), and/or supplying additional fluid when needed via reservoir drain 813. In some embodiments, reservoir drain 813 is configured to be automatically fluidly coupled to manifold circuit 832 by the actuation of a reservoir drain 813 associated control valve 840. In some embodiments, venturi 830 is configured to enable the movement of fluid between the cooling tank 816 and the reservoir 810, utilizing pressure differences between the reservoir 810 and the manifold circuit 832. Venturi 830 may be replaced by a pump, and/or used in conjunction with a pump 831 to enhance fluid transfer capabilities, in accordance with some embodiments.

In some embodiments, vent 811 is configured to allow for the release of air and/or excess fluid from the reservoir 810. In some embodiments, level sensors 820 monitor the fluid levels within the cooling tank 816 and/or the reservoir 810, providing near real-time (e.g., within 1 minute) data for maintaining optimal fluid levels and ensuring efficient cooling. In some embodiments, containment tank 808 provides an additional layer of safety for rack 801 to prevent fluid overflow and ensure the system operates safely under various conditions.

In some embodiments, one or more cooling distribution units (CDU) 870 fluidly coupled to the manifold circuit 832 are configured to distribute cooling fluid and maintain optimal temperature setpoints. In some embodiments, CDU 870, cold circuit 860, and/or hot circuit 850 form part of a cooling circuit (e.g., FIG. 9) that manages heat removal.

Non-limiting characteristics of the system described in FIG. 8 and/or used in some embodiments include specifications such as 50-150 kPa for the manifold circuit pump, 25-75 m3/Hr flow through the manifold circuit, a reservoir containment volume between 17.5 and 57.5, a cold circuit and/or hot circuit circulating fluid at 10-30 m3/Hr, and/or circuit piping ranging from 6-18 inches. Rack specifications, according to some embodiments, include 384-584 Gal, Area=2504−2704 in², with an expansion volume of 4.5-24.5 Gal. In some embodiments, external plumbing can range between 262 and 462 Gal, with an expansion volume of 6-16 Gal, which is taken into account by the system when determining changes in levels due to fluid displacement equipment removal/addition, according to some embodiments. In some embodiments, servers may occupy between approximately 34 and 74 rack units (RU), with each rack unit displacing approximately 1 to 1.24 gallons of fluid per RU. In some embodiments, the total displacement volume for these servers may range from approximately 30.5 to 90.5 gallons. In some embodiments, the system is configured to account for both volume and system characteristics when determining an amount of fluid to add and/or remove.

FIG. 9 illustrates a portion of the cooling infrastructure of the immersion cooling system 800, in accordance with some embodiments. In some embodiments, cold circuit 860 is configured to circulate cooled fluid throughout the system, absorbing heat generated by fluid displacing equipment, immersed in the cooling tank 806, preventing overheating and ensuring optimal performance. In some embodiments, hot circuit 850 is configured to transport the heated fluid away from the cooling tank 806 to the cooling distribution unit (CDU) 870. In some embodiments, the CDU 870 is configured to dissipate the absorbed heat, cooling the fluid before it is recirculated back into the system via the cold circuit 860. The cycle of heat absorption and dissipation ensures that the cooling fluid remains effective in managing the thermal load of the system. In some embodiments, racks may range in current fluid from 420-450 Gal, and/or reservoirs may have ranges from 50-30 Gal, as non-limiting examples, according to some embodiments. In some embodiments, the system is configured to determine a current amount of fluid in each rack and/or reservoir and prevent one or more racks from falling below one or more setpoints for component coverage and/or to achieve a substantially consistent fluid level among all the racks and/or reservoirs.

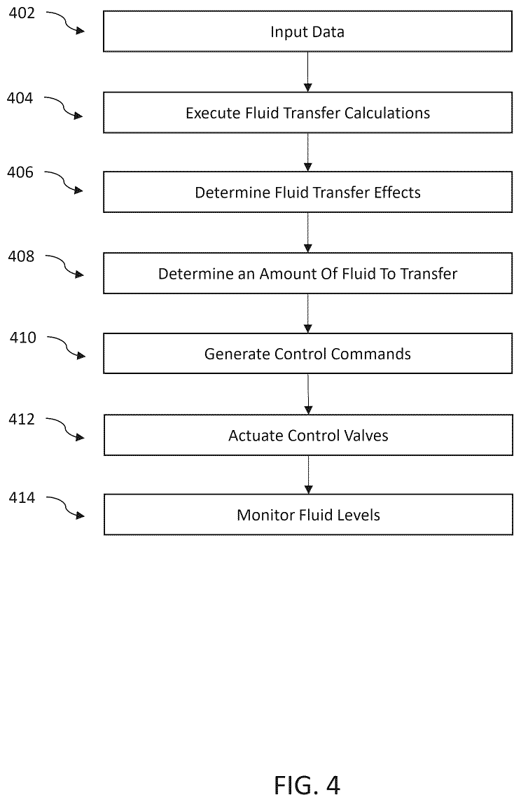

In some embodiments, the interaction between cold circuit 860 and hot circuit 850 is controlled by control engine 200, which adjusts fluid flow rates and temperature setpoints based on data from one or more sensors 110, such as level sensors 820, for example. In some embodiments, control valves 820 are strategically placed throughout the system to regulate the flow of fluid, allowing for precise and accurate control over the cooling process as well as isolation of specific racks 801. In some embodiments, one or more control valves 820 are actuated by the control engine 200, which processes data from sensors 110, database 108, and/or UEs 102, to implement the level control described further in relation to FIGS. 3 and 4. A recitation of “control engine 200” or a “controller” may be replaced with the “system” when defining the metes and bounds of the disclosure, as implementations of the system are not limited to the control infrastructure described herein.

Turning now to FIG. 3, process 300 provides non-limiting example embodiments for component addition and/or removal in the disclosed system. According to some embodiments, process 300 provides non-limiting embodiments for the framework through which the disclosed system (e.g., via control engine 200) can control, manage, and manipulate fluid levels within the rack. Steps described in the figures represent both an execution of a computer algorithm and a method of implementing the system during an add state, where fluid displacing equipment is added, and a remove state, in which fluid displacing information technology (IT) equipment is removed. In some embodiments, a state can be automatically detected and implemented through the system identification of the component added and/or removed (e.g., after a change in electrical connection), and/or can be initiated by a user via UE 102.

According to some embodiments, steps 302-304 of process 300 can be performed by the input module 202 of control engine 200; Steps 306-308 can be performed by the transformation module 204; steps 310, 312, and 318 can be performed by the analysis module 206; and steps 314, 316, and 320 can be performed by the output module 208.

In some embodiments, process 300 begins with step 302, where data is retrieved from one or more sensors, including fluid level sensors and/or temperature sensors, to assess the current state of the cooling tank and reservoir. In step 304, the total volume of one or more fluid displacing component to be removed and/or replaced, such as servers and CPUs, is calculated based on pre-stored data, component models, and/or user input, as non-limiting examples, in accordance with some embodiments. Step 306 includes analyzing temperature data to assess its impact on fluid density, volume, and/or thermal requirements of the rack, and adjusting fluid level calculations, if needed, in accordance with some embodiments. In step 308, the necessary fluid level adjustments required to maintain coverage of one or more components within the cooling tank and/or prevent overflow of the cooling tank are determined, in accordance with some embodiments. In some embodiments, the coverage determined includes determining a volume of fluid to deliver to the cooling tank to replace the volume of cooling fluid displaced by the one or more components. In some embodiments, the coverage determined includes determining a volume of fluid to remove from the cooling tank to prevent overflow of the cooling tank. In some embodiments, the coverage determined includes determining an amount (e.g., volume) of fluid to deliver to the cooling tank to maintain the fluid level between an upper and/or lower setpoint when the one or more components are removed. In some embodiments, the setpoints include levels that prevents servers and/or CPUs from exposure to gas (e.g., air).

In some embodiments, step 310 includes determining a level change in the cooling tank caused by the removal and/or addition of the one or more components. In step 312, control commands are generated to adjust fluid levels, including opening, or closing control valves and activating pumps and/or venturi devices, in accordance with some embodiments. In step 314, one or more control valves are actuated to regulate fluid flow, which may include closing, opening, and/or throttling or one or more control valves, such as those depicted in FIGS. 8 and 9, for example, in accordance with some embodiments. In some embodiments, artificial intelligence (AI) is used in conjunction with one or more calculation or control implementations described herein.

Step 316 includes activating pumps or venturi devices to facilitate fluid movement between the cooling tank and reservoir, in accordance with some embodiments. In some embodiments, step 318 includes executing an analysis on the actual volume/level change from the removal of the equipment and the calculated level change. In some embodiments, the system is configured to update the database with actual data at the time of removal, which may include level, change, volume calculated, temperature before change, temperature after change, and/or any other measured or calculated parameter to better refine a model. In some embodiments, step 320 includes monitoring fluid levels and component volumes and/or updating calculations and control commands as needed. In some embodiments, the results of the transfer are used to train one or more AI models to better predict the results of component removal and/or addition.

FIG. 4 depicts non-limiting steps included in a fluid transfer process 400 between one or more racks and/or one or more reservoirs, in accordance with some embodiments. The steps of process 400, as well as any process steps described herein, may be combined with one or more steps from process 300 to maintain target levels within one or more racks. In some embodiments, process 400 describes how to simultaneously maintain levels in a plurality of racks by transferring fluid between racks in response to system determinations.

According to some embodiments, steps 402-404 of process 400 can be performed by the input module 202 of control engine 200; steps 406-408 can be performed by the transformation module 204; steps 410 and 412 can be performed by the analysis module 206; and steps 414 can be performed by the output module 208.

In some embodiments, process 400 begins with step 402, where data is retrieved from one or more databases and/or one or more sensors, including fluid level sensors, temperature sensors, camera, and/or any other sensor describe herein, to assess the current state of a plurality of cooling tanks. In step 404, the volume of fluid required for transfer between racks while maintaining setpoint levels in all racks is determined. In some embodiments, the determination is based on pre-stored data, rack models, user input, and/or artificial intelligence (AI), in accordance with some embodiments. In some embodiments, determining an amount to transfer calculation may include determining the current fluid levels in the source and destination racks and identifying the required adjustments to maintain optimal fluid levels in one or more other racks in an immersion cooling platform using flowrates, component volumes, and/or platform volumes, such as the non-limiting example platform volumes associated with various figures described herein. In some embodiments, the system is configured transfer fluid from a reservoir (e.g., buffer cooling tank) associated with a rack while maintaining a fluid level within the rack at a desired setpoint and/or range.

In some embodiments, step 406 includes determining the impact of fluid transfer on the thermal and operational requirements of the racks. In some embodiments, this step includes analyzing temperature data from one or more sensors to assess the incoming and/or outgoing fluid's effect on fluid density and volume within one or more cooling tanks, ensuring that heat producing components remained fluidly covered during the transfer. In step 408, the necessary adjustments to fluid levels in both the source and destination racks are determined, including the volume of fluid to be transferred and the flow rate required to achieve the desired levels within a specified timeframe, in accordance with some embodiments.

Step 410 includes generating control commands to execute the fluid transfer, including opening or closing control valves or drains and activating pumps and/or venturis, in accordance with some embodiments. These commands are configured to regulate fluid flow between racks while maintaining system balance and preventing overflow or underfill conditions, in accordance with some embodiments. In step 412, one or more control valves are actuated to initiate fluid transfer, which may include throttling, opening, or closing valves as depicted in FIGS. 8 and 9, for example, in accordance with some embodiments.

In some embodiments, step 414 includes monitoring fluid levels and flow rates to verify that the transfer is proceeding as planned. In some embodiments, the system updates the database with actual data from the transfer, including fluid levels before and after the transfer, flow rates, temperature changes, and any other relevant parameters. In some embodiments, this data is used to train one or more AI models, as further described below.

In some embodiments, such computational analysis can involve control engine 200 executing any type of known or to be known computational analysis technique, algorithm, mechanism, or technology. In some embodiments, control engine 200 may include one or more trained artificial intelligence (AI) models.

In some embodiments and, optionally, in combination of any embodiment described above or below, an AI model may include a neural network that may be one of, without limitation, feedforward neural network, radial basis function network, recurrent neural network, convolutional network (e.g., U-net) or other suitable network, such as the non-limiting examples below. In some embodiments and, optionally, in combination of any embodiment described above or below, an implementation of neural network may be executed as follows:
a. define neural network architecture/model for the control framework,
b. transfer the input data to the neural network model,
c. train the model incrementally,
d. determine the accuracy for a specific number of timesteps,
e. apply the trained model to process the newly received input data,
f. optionally and in parallel, continue to train the trained model with a predetermined periodicity.

In some embodiments and, optionally, in combination of any embodiment described above or below, the trained AI model may specify a neural network by at least a neural network topology, a series of activation functions, and connection weights. For example, the topology of a neural network may include a configuration of nodes of the neural network and connections between such nodes. In some embodiments and, optionally, in combination of any embodiment described above or below, the trained AI model may also be specified to include other parameters, including but not limited to, bias values/functions and/or aggregation functions. For example, an activation function of a node may be a step function, sine function, continuous or piecewise linear function, sigmoid function, hyperbolic tangent function, or other type of mathematical function that represents a threshold at which the node is activated. In some embodiments and, optionally, in combination of any embodiment described above or below, the aggregation function may be a mathematical function that combines (e.g., sum, product, and the like) input signals to the node. In some embodiments and, optionally, in combination of any embodiment described above or below, an output of the aggregation function may be used as input to the activation function. In some embodiments and, optionally, in combination of any embodiment described above or below, the bias may be a constant value or function that may be used by the aggregation function and/or the activation function to make the node more or less likely to be activated.

Non-limiting example AI models, according to some embodiments, include a Convolutional Neural Network (CNN). In some embodiments, a CNN is utilized for sensor data processing such as recited in Steps 302 and 402. In some embodiments, the CNN is trained using labeled datasets comprising structured sensor readings, such as spatially or temporally structured fluid-level and temperature measurements, paired with corresponding environmental or operational states (e.g., normal operation, overflow risk, temperature anomalies, fluid displacing component removal/addition). In some embodiments, the CNN is configured to process multi-dimensional sensor data—such as spatially-distributed sensor grids, image-based sensor outputs, or sensor data transformed into image-like formats—and extract relevant spatial-temporal features to assess the current condition and operational state of the cooling tanks, reservoirs, and racks.

In some embodiments, a regression model, such as gradient boosting, is used for volume and level predictions, such as those recited in steps 304, 306, and 404. In some embodiments, the regression model is trained using datasets containing component-specific parameters (e.g., physical dimensions and known displacement volumes), user-defined inputs, and historical data reflecting fluid displacement events. In some embodiments, the regression model is configured to calculate the total volume of fluid displaced by various components and to predict fluid-level changes over time. In some embodiments, the regression model calculates fluid volumes and flow rates necessary to maintain setpoint levels during fluid transfers between racks, providing accurate and efficient predictions to support fluid management tasks. In some embodiments, a regression model is configured to calculate the total volume of fluid displaced by components and predict fluid level changes over time based on component removal or addition scenarios. In some embodiments, a regression model calculates fluid volumes and flow rates required for maintaining setpoint levels during fluid transfer between racks during a component removal/addition.

In some embodiments, a physics-informed neural network (PINN) is used for temperature impact analysis, such as those recited in steps 310 and 406. In some embodiments, the PINN is configured by embedding governing equations relating temperature, fluid density, volume changes, and thermal characteristics into the neural network's loss functions or training process. In some embodiments, the PINN is trained using both empirical datasets (e.g., temperature measurements, observed fluid density, and volumetric responses) and constraints derived from physical laws (e.g., thermodynamics, fluid mechanics equations). In some embodiments, the PINN analyzes temperature data to predict its impact on fluid density, volume, and overall thermal management requirements.

In some embodiments, the system includes one or more reinforcement learning (RL) models, which may include, as non-limiting examples, Deep Q-Networks (DQN) for discrete control actions and Proximal Policy Optimization (PPO) for continuous or mixed control actions. In some embodiments, the reinforcement learning models are configured to generate commands for fluid adjustments, control commands, valve actuation, and/or pump operations, such as those recited in steps 308, 312, 314, 316, 408, 410, and/or 412. In some embodiments, these RL models are iteratively trained using simulated or historical scenarios that vary fluid levels, flow rate requirements, operational parameters, and environmental conditions. In some embodiments, a reinforcement learning model is configured to determine necessary fluid adjustments to maintain fluid levels within predefined setpoint ranges and generate corresponding control commands. In some embodiments, the reinforcement learning model is configured to regulate fluid flow through control actions such as actuating valves (e.g., discrete commands for opening and closing or continuous throttling commands) and activating or adjusting pump speeds or venturi devices to achieve desired fluid movements. In some embodiments, these RL models leverage shared training data or experience buffers, enabling optimization of fluid management strategies across multiple operational steps described herein.

In some embodiments, an error analysis model, such as a Bayesian network, is used for identifying and analyzing discrepancies between predicted and actual fluid-level changes, such as those that may occur in step 318. In some embodiments, the Bayesian network is configured with nodes representing predicted fluid levels, actual measured fluid levels, component characteristics, operational parameters, and potential sources of error. In some embodiments, historical operational data reflecting predicted versus actual fluid level changes is used to infer probabilistic relationships and conditional dependencies between these nodes. In some embodiments, the Bayesian network analyzes observed discrepancies, identifies potential root causes, and quantifies uncertainties, thereby enabling refinement of fluid displacement and predictive component models. This iterative error analysis improves prediction accuracy and enhances the system's ability to adapt effectively to real-world variations in fluid displacement, environmental conditions, and operational scenarios.

In some embodiments, a learning model, such as an incremental regression model or recurrent neural network (RNN), is used for monitoring and executing adjustments, as listed in steps 320 and/or 414, for example. In some embodiments, the learning model is incrementally trained through feedback loops incorporating real-time sensor data and executed control commands gathered during fluid management operations. In some embodiments, the learning model continuously monitors fluid levels, flow rates, and transfer progress, dynamically verifies fluid management performance, and adaptively updates control commands and operational calculations in real-time. In some embodiments, the learning model updates database records with actual measured outcomes from fluid transfers—including observed fluid levels, flow rates, and temperature changes—to continuously refine its predictions and optimize future fluid management operations.

FIG. 7 is a schematic diagram illustrating a client device showing an example embodiment of a client device that may be used within the present disclosure and/or the framework illustrated in FIG. 1, in accordance with some embodiments. In some embodiments, client device 700 may include many more or fewer components than those shown in FIG. 7, such as a plurality of computers. However, the components shown are sufficient to disclose an illustrative embodiment for implementing the present disclosure, in accordance with some embodiments. In some embodiments, client device 700 may represent, for example, UE 102 discussed above at least in relation to FIG. 1: UE 102 may also represent any controller described herein.

As shown in FIG. 7, in some embodiments, client device 700 includes one or more processors (CPU) 722 in communication with one or more non-transitory computer readable media 730 via a bus 724. In some embodiments, client device 700 also includes a power supply 726, one or more network interfaces 750, an audio interface 752, a display 754, a keypad 756, an illuminator 758, an input/output interface 760, a haptic interface 762, an optional global positioning systems (GPS) receiver 764 and/or sensors 110 (e.g., optical, thermal, level, positional, pressure, proximity, capacitive, inductive, magnetic, acoustic, humidity, flow, vibration, current, voltage, gas, chemical, pH, force, torque, strain, gyroscopic, accelerometric, light, infrared, ultraviolet, microwave, radar, ultrasonic, biosensors, image sensors, and/or motion sensors). In some embodiments, client device 700 can include and/or be coupled to one or more sensors 110, such as the example sensors described herein, as understood by those of skill in the art. In some embodiments, client device 700 may communicate with one or more controllers, and/or directly with another computing device. In some embodiments, network interface 750 is sometimes known as a transceiver, transceiving device, or network interface card (NIC).

In some embodiments, audio interface 752 is arranged to produce and receive audio signals such as the sound of a human voice in some embodiments. In some embodiments, display 754 may be a liquid crystal display (LCD), gas plasma, light emitting diode (LED), or any other type of display used with a computing device. In some embodiments, display 754 may also include a touch sensitive screen arranged to receive input from an object such as a stylus or a digit from a human hand. Keypad 756 may include any input device arranged to receive input from a user; illuminator 758 may provide a status indication and/or provide light, in accordance with some embodiments.

Client device 700 also includes input/output interface 760 for communicating with external. Input/output interface 760 can utilize one or more communication technologies, such as USB, infrared, Bluetooth™, or the like, in some embodiments. In some embodiments, haptic interface 762 is arranged to provide tactile feedback to a user of the client device.

In some embodiments, optional GPS transceiver 764 can determine the physical coordinates of client device 700 on the surface of the Earth, which typically outputs a location as latitude and longitude values. GPS transceiver 764 can also employ other geo-positioning mechanisms, including, but not limited to, triangulation, assisted GPS (AGPS), E-OTD, CI, SAI, ETA, BSS or the like, to further determine the physical location of client device 700 on the surface of the Earth. In some embodiments, however, client device 700 may, through other components, provide other information that may be employed to determine a physical location of the device, including for example, a MAC address, Internet Protocol (IP) address, or the like.

In some embodiments, mass memory 730 includes a RAM 732, a ROM 734, and/or other non-transitory storage means. In some embodiments, mass memory 730 illustrates another example of computer storage media for storage of information such as computer readable instructions, data structures, program modules, usage data, or other data. In some embodiments, mass memory 730 stores a basic input/output system (“BIOS”) 740 for controlling low-level operation of client device 700. In some embodiments, the mass memory also stores an operating system 741 for controlling the operation of client device 700.

In some embodiments, memory 730 further includes one or more data stores (e.g., database 108), which can be utilized by client device(s) 700 to store, among other things, applications 742 for executing control engine 200, and/or other information or data. For example, data stores may be employed to store information that describes various capabilities of client device 700. The information may then be provided to another device based on any of a variety of events, including being sent as part of a header (e.g., index file of the HLS stream) during a communication, sent upon request, or the like. In some embodiments, at least a portion of the capability information may also be stored on a disk drive or other storage medium (not shown) within client device 700.

In some embodiments, applications 742 may include computer executable instructions which, when executed by client device 700, transmit, receive, and/or otherwise process data such as audio, video, images, and enable telecommunication with a server and/or another user of another client device. In some embodiments, applications 742 may further include a client that is configured to send, to receive, and/or to otherwise process goods/services and/or other forms of data, messages and content hosted and provided by the platform associated with control engine 200 and its affiliates.

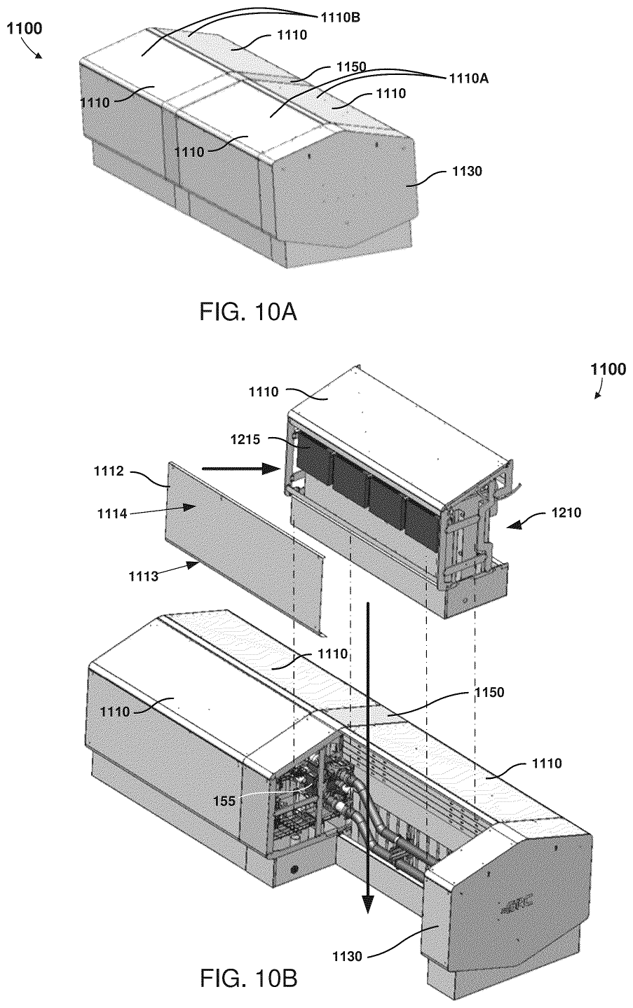

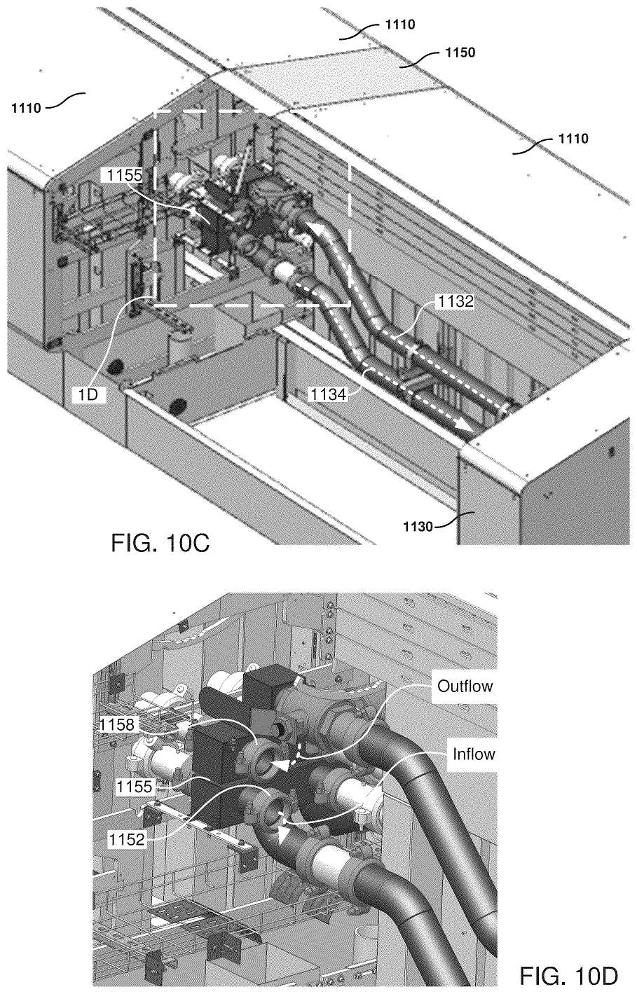

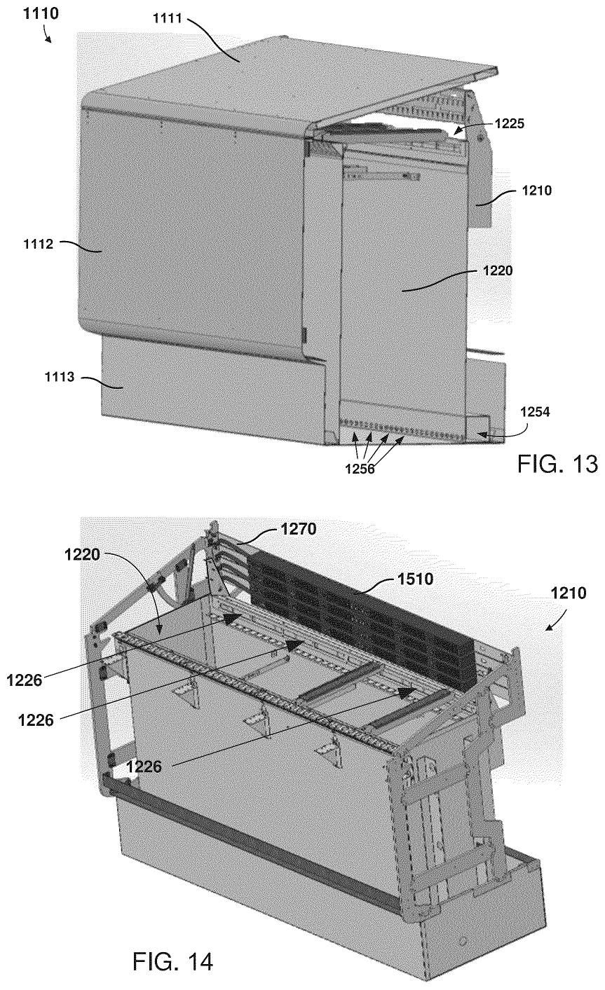

As discussed supra, in some embodiments, the system includes methods and apparatus for cooling multiple immersion cooling tanks with a single coolant distribution system. Further examples of system configurations are presented below in relation to FIGS. 10-21, in accordance with some embodiments.

In some embodiments, the system may include one or more coolant distribution units, a coolant manifold circuit, a supply and return line, and one or more immersion cooling racks. In some embodiments, the coolant distribution unit may be configured to adjust a temperature and pump a fluid used as a coolant. In some embodiments, the coolant manifold may redistribute the fluid. In some embodiments, the supply line may be coupled to the coolant distribution unit and the coolant manifold. In some embodiments, the supply line may be configured to convey the coolant fluid from the coolant distribution unit to the coolant manifold. In some embodiments, the return line may be coupled to the coolant distribution unit and the coolant manifold. In some embodiments, the return line may be configured to convey the coolant fluid from the coolant manifold to the coolant distribution unit. In some embodiments, a first pair of immersion cooling racks may be disposed between the coolant distribution unit and the coolant manifold. In some embodiments, each immersion cooling rack of the first pair of immersion cooling racks may be coupled to the coolant manifold through a first inlet duct for receiving the coolant fluid from the coolant manifold and a first outlet duct for returning the coolant fluid to the coolant manifold.

In some embodiments, a second pair of immersion cooling racks may be disposed on an opposite side of the coolant manifold relative to the first pair of immersion cooling racks, wherein each immersion cooling rack of the second pair of immersion cooling racks is coupled to the coolant manifold through a second inlet duct for receiving the coolant fluid from the coolant manifold and a second outlet duct for returning the coolant fluid to the coolant manifold.

In some embodiments, at least one of the first inlet duct or the first outlet duct in each immersion cooling rack may be an adjustable valve configured to selectively restrict coolant fluid flow between the coolant manifold and the respective immersion cooling rack. In some embodiments, each of the first pair of immersion cooling racks may include a thermal switch that is triggered when a temperature of the coolant fluid drops below a threshold temperature, wherein the triggering of the thermal switch restricts fluid flow through the adjustable valve. In some embodiments, at least one of the first inlet duct or the first outlet duct in each immersion cooling rack may be a one-way valve.

In some embodiments, a plurality of inlet ports may be located in each of the first pair of immersion cooling racks, wherein the plurality of inlet ports are adjustable to control an orientation of a flow of coolant fluid through each respective immersion cooling rack. In some embodiments, each of the plurality of inlet ports may comprise an adjustable nozzle or jet to control the orientation of the flow of coolant fluid through each respective immersion cooling rack. In some embodiments, each of the plurality of inlet ports may comprise an adjustable coolant fluid valve to control the flow pressure of coolant fluid passing through the respective inlet port, wherein flow pressure controlled by the adjustable coolant fluid valve may constructively or destructively interfere with coolant fluid flow through adjacent inlet ports to control the orientation of the flow of coolant fluid through each respective immersion cooling rack.

In some embodiments, the system is configured for controlling temperature measured in multiple immersion cooling racks with a single coolant distribution system, such as that described in relation to FIGS. 8 and 9, as well as the other non-limiting examples provided below. In some embodiments, the system may include a component cooling tank, a buffer cooling tank, and a weir. In some embodiments, the component cooling tank is configured to hold at least one electronic component at least partially submerged in a coolant fluid pumped into the component cooling tank. In some embodiments, a weir may extend along an upper edge of a barrier separating the component cooling tank from the buffer cooling tank, wherein the weir is configured to allow excess coolant fluid from the component cooling tank to spill out of the component cooling tank, over the weir, and into the buffer cooling tank.

In some embodiments, the coolant fluid may be pumped into the component cooling tank from inlet ports along a bottom of a sidewall of the component cooling tank. Some embodiments include a whirlpool shield mounted inside the buffer cooling tank above an outlet port for the coolant fluid to exit the buffer cooling tank, wherein a first end of the whirlpool shield is attached to a side wall of the buffer cooling tank and the whirlpool shield extends away from the first end toward a second end disposed further from the outlet port than the first end. In some embodiments, the whirlpool shield may extend downward at an angle such that the second end of the whirlpool shield is vertically lower than the first end of the whirlpool shield.

In some embodiments, the system includes devices, systems, and methods for controlling the temperature of multiple immersion cooling racks with a single coolant distribution system. In some embodiments, the system includes a coolant distribution unit, a coolant manifold, a supply and return line, and one or more immersion cooling racks. In some embodiments, the coolant distribution unit is configured to adjust a temperature and pump a fluid used as a coolant. In some embodiments, the coolant manifold is configured to redistribute the coolant fluid. In some embodiments, the supply line is coupled to the coolant distribution unit and the coolant manifold. In some embodiments, the supply line is configured to convey the coolant fluid from the coolant distribution unit to the coolant manifold. In some embodiments, the return line is coupled to the coolant distribution unit and the coolant manifold. In some embodiments, the return line is configured to convey the coolant fluid from the coolant manifold to the coolant distribution unit. In some embodiments, a first pair of immersion cooling racks is disposed between the coolant distribution unit and the coolant manifold. In some embodiments, each immersion cooling rack of the first pair is coupled to the coolant manifold through a first inlet duct for receiving the coolant fluid from the coolant manifold and a first outlet duct for returning the coolant fluid to the coolant manifold.

In some embodiments, the component cooling tank is configured to hold at least one electronic component at least partially submerged in a coolant fluid pumped into the component cooling tank. In some embodiments, the weir extends along an upper edge of a barrier separating the component cooling tank from the buffer cooling tank. In some embodiments, the weir is configured to allow excess coolant fluid from the component cooling tank to spill out of the component cooling tank, over the weir, and into the buffer cooling tank.

In some embodiments, the immersion cooling racks provide a bath of fluid in a tank. In some embodiments, the fluid is circulated such that heat is rejected from the fluid to the atmosphere, typically via an external cooling device such as an evaporative cooling tower. In some embodiments, the cooled fluid is delivered to heat-generating, electronic, fluid displacing components that would otherwise overheat. In some embodiments, circulation of fluid occurs by natural convection due to density changes as fluid is heated, wherein hot coolant is less dense and tends to rise to the top of the tank. In some embodiments, the circulation of coolant fluid is achieved by active pumping from a manifold into the bottom of one or more fluid tanks.

In some embodiments, the system includes multiple racks coupled together to increase the number and volume of computer system components that may be cooled. In some embodiments, the computer system components are distributed across multiple racks to reduce the size of each rack and simplify movement and placement in a location. In some embodiments, a single coolant distribution unit, such as a CDU, is configured to cool coolant fluid passed through multiple individual racks. In some embodiments, the system is configured to improve efficiency by using a single coolant distribution unit to service a plurality of racks.

As described above, in some embodiments, the system includes fluid displacing information technology (IT) equipment disposed within the component cooling tank. In some embodiments, the IT equipment has a depth or width such that passive recirculation of fluid, such as that resulting from temperature or density variations, is insufficient to evenly distribute cool fluid throughout the equipment. In some embodiments, the system includes a pump and/or one or more jets configured to optimize cooling across all IT equipment. In some embodiments, the jets are located at the bottom of the tank and are oriented such that cool fluid is distributed across the bottom of the tank. In some embodiments, the orientation of the jet flow is adjustable to suit product design requirements. In some embodiments, the adjustment of jet orientation is configured to control and manipulate coolant flow over particular locations and components in the tank. In some embodiments, the adjustment is achieved through physical manipulation of nozzles or jets. In some embodiments, the adjustment is achieved through control of flow rates to generate constructive or destructive wave interference. In some embodiments, the jets are angled (not horizontal) for use with immersion systems that include fluid displacing IT equipment with a shorter chassis.

In some embodiments, FIGS. 10A-10D illustrate various aspects of a multi-rack cooling system in accordance with some embodiments, such as those described in relation to FIGS. 8 and 9, where the predictive level control system described herein are integrated.

In some embodiments, FIG. 10A illustrates a multi-rack cooling system 1100. In some embodiments, the multi-rack cooling system 1100 includes four immersion cooling rack assemblies 1110 set up in rows, a coolant distribution unit 1130, and a coolant manifold unit 1150. In some embodiments, additional immersion cooling rack assemblies 1110 may be included in conjunction with the coolant distribution unit 1130 and the coolant manifold unit 1150, as illustrated in FIG. 9. In some embodiments, the multi-rack cooling system includes 2, 4, 6, 8, etc. immersion cooling rack assemblies 1110 in conjunction with the coolant distribution unit 1130 and the coolant manifold unit 1150. In some embodiments, the coolant distribution unit 1130 is configured pump a fluid used as a coolant into each of the plurality of immersion cooling rack assemblies 1110 to adjust a temperature (e.g., cool down). In some embodiments, the fluid includes a liquid dielectric, which includes a thermally conductive fluid configured to prevent or rapidly quench electric discharges. In some embodiments, the coolant manifold unit 1150 is configured to redistribute the fluid between the coolant distribution unit 1130 and the plurality of immersion cooling rack assemblies 1110. In some embodiments, each of the immersion cooling rack assemblies 1110 includes a component cooling tank configured to hold at least one electronic component fully, or at least partially, submerged in a fluid pumped into the component cooling tank.

In some embodiments, pairs of the immersion cooling rack assemblies 1110 are arranged (e.g., side-by-side) in the multi-rack cooling system 1100. In some embodiments, a first pair of immersion cooling rack assemblies 1110A is disposed between the coolant distribution unit 1130 and the coolant manifold unit 1150. In some embodiments, a second pair of immersion cooling rack assemblies 1110B is disposed on an opposite side of the coolant manifold unit 1150 relative to the first pair of immersion cooling rack assemblies 1110A.

In some embodiments, multiple immersion cooling rack assemblies 1110 are used in parallel to reduce the cost per space of cooling. For example, in some embodiments, four immersion cooling rack assemblies 1110 of approximately 50 U may be connected to a single pump. In some embodiments, a datacenter employs the same information technology load in each area or immersion cooling rack assembly 1110. In some embodiments, collocation facilities include significantly different loads from one immersion cooling rack to another. In some embodiments, a customer requires only a single rack of space, which needs fewer resources than a customer using multiple racks.

In some embodiments, equal cooling is provided across the plurality of immersion cooling racks, even without any flow regulation between the plurality of immersion cooling rack assemblies 1110. In some embodiments, the cooling flow is scaled to handle the hottest of the plurality of immersion cooling rack assemblies 1110, which enables the pumping system to work as hard as if the most power-dense rack was the average heat-generating rack.

In some embodiments, the system includes flow regulation that adjusts and varies the flow of coolant fluid to each of the plurality of immersion cooling rack assemblies 1110. In some embodiments, this adjustability allows for reduced power usage of a pump while maintaining the densest immersion cooling rack assembly 1110 by diverting flow to the dense immersion cooling rack assembly 1110 rather than increasing flow to all immersion cooling rack assemblies 1110. In some embodiments, the maximum capacity of the coolant distribution unit 1130 becomes the sum of the immersion cooling racks' power, rather than four times (4×) the peak power rack, which enables higher density racks.

For example, if a coolant distribution unit 1130 has a capacity of 100 kW, the immersion cooling racks may have the following loads:
a. 25, 25, 25, 25 (i.e., even loading, no capacity or efficiency is wasted); or
b. 25, 25, 15, 15 (i.e., uneven loading, associated with wasted efficiency).

If adjustable valves are included for balancing fluid level, the following loads may be possible:
a. 25, 25, 15, 15 (i.e., flow diverted from 15 kW racks to improve efficiency); or
b. 35, 35, 15, 15 (i.e., divert flow from 15 kW to boost capacity of racks over max/4).

In some embodiments, heat loads are dynamic, and the system is configured to divert flow automatically, such as by controlling inlet and outlet temperatures. In some embodiments, a temperature sensor on the exhaust is used to control the amount of fluid flowing through the rack. In some embodiments, the fluid entering each rack acts like fluid cooled by the heat exchanger directly. In some embodiments, heat load is proportional to the flow rate, which is measured by the difference between inlet and exhaust temperatures (dT). In some embodiments, if an immersion cooling rack has a low difference between temperatures, that rack's flow is constricted to maintain a constant dT. In some embodiments, a main pump is controlled by those temperatures or by providing a constant pressure. In some embodiments, under a constant pressure method, when valves close, the pump slows down and maintains flow to the least restricted immersion cooling rack.

In some embodiments, FIG. 10B illustrates a partially exploded view of the multi-rack cooling system 1100 in FIG. 10A. In FIG. 10B, one immersion cooling rack assembly 1110 is removed from its station in the multi-rack cooling system 1100. An outside panel 1112 of the removed immersion cooling rack assembly 1110 is pulled away to reveal electronic components 1215 attached to an outer side of a frame 1210 forming the immersion cooling rack assembly 1110, in accordance with some embodiments. In some embodiments, the electronic components 1215 include switches, batteries, transformers, and/or other components of the immersion cooling rack assembly 1110 that do not need to be submerged in coolant. In some embodiments, the outside panel 1112 at its base 1113 is configured to lie closer to the frame 1210 than an upper portion 1114, which makes room for the electronic components 1215 while forming a toe-kick area at the base 1113. In some embodiments, the toe-kick area at the base 1113 allows technicians to stand more comfortably close to the sides of the multi-rack cooling system 1100 while servicing and maintaining the multi-rack cooling system 1100.

In some embodiments, FIG. 10B illustrates a lid and side panel of one side of the coolant manifold unit 1150 removed to reveal the coolant manifold 1155 located therein. In some embodiments, the coolant manifold 1155 receives cooled coolant fluid from the coolant distribution unit 1130 via plumbing (supply line 1132 and return line 1134) and redistributes the cooled coolant fluid to each of the individual immersion cooling rack assemblies 1110. In some embodiments, the compartment inside the coolant manifold unit 1150 includes sensors for checking temperature, detecting leaks of coolant fluid, and/or detecting the accumulation of water from condensation or other sources.

In some embodiments, FIG. 10C is a relief view of the partially exploded view of the multi-rack cooling system 1100 in FIG. 10B. In FIG. 10C, a supply line 1132 is shown coupling the coolant distribution unit 1130 and the coolant manifold 1155. In some embodiments, the supply line 1132 is configured to convey fluid from the coolant distribution unit 1130 to the coolant manifold 1155. In some embodiments, FIG. 10C further shows a return line 1134 coupling the coolant distribution unit 1130 and the coolant manifold 1155. In some embodiments, the return line 1134 is configured to convey the coolant fluid, heated by contact with components housed in the immersion cooling racks, from the coolant manifold 1155 to the coolant distribution unit 1130. In some embodiments, the supply line 1132 delivers cooled coolant fluid to the coolant manifold 1155, and the return line 1134 returns heated coolant fluid to the coolant distribution unit 1130.

In some embodiments, FIG. 10D is a further relief view of the multi-rack cooling system 1100 in FIG. 10C. In FIG. 10D, the coolant manifold 1155 includes inlet ducts (i.e., inflow) and outlet ducts (i.e., outflow) configured to be coupled to an immersion cooling rack assembly 1110. In some embodiments, an immersion cooling rack assembly 1110 of the first pair of immersion cooling rack assemblies 1110A is coupled to the coolant manifold 1155 through a first inlet duct 1152 for receiving fluid from the coolant manifold 1155. In some embodiments, the coolant manifold 1155 supplies the attached immersion cooling rack assembly 1110 with an inflow of coolant fluid through the first inlet duct 1152. In some embodiments, the immersion cooling rack assembly 1110 of the first pair of immersion cooling rack assemblies 1110A is also coupled to the coolant manifold 1155 through a first outlet duct 1158 for returning the heated coolant fluid to the coolant manifold 1155. In some embodiments, the coolant manifold 1155 receives the outflow of coolant fluid through the first outlet duct 1158. In some embodiments that include four immersion cooling rack assemblies 1110 (as shown in FIGS. 10A-10D), the coolant manifold 1155 includes four sets of inlet and outlet ducts, each coupled to a different immersion cooling rack assembly 1110. In some embodiments in which the number of immersion cooling racks varies, the number of inlet and outlet duct pairs also varies. In some embodiments, a second immersion cooling rack assembly 1110 of the second pair of immersion cooling rack assemblies 1110B is coupled to the coolant manifold 1155 through a second inlet duct 1152 and a second outlet duct 1158. In some embodiments, ducts 1152 and 1158 include a valve or other flow control element.

In some embodiments, a partial solution to a potential coolant level imbalance that occurs when multiple immersion cooling rack assemblies 1110 with component cooling tanks are supported by a single pump and heat exchanger (i.e., coolant distribution unit 1130) is to include a weir between a main cooling tank 1220 and a buffer cooling tank 1230 (i.e., reservoir), both included in each immersion cooling rack (1110, 1210). In some embodiments, overflow may be gravity drained to a reservoir 812 distal from the main cooling tank 1220.

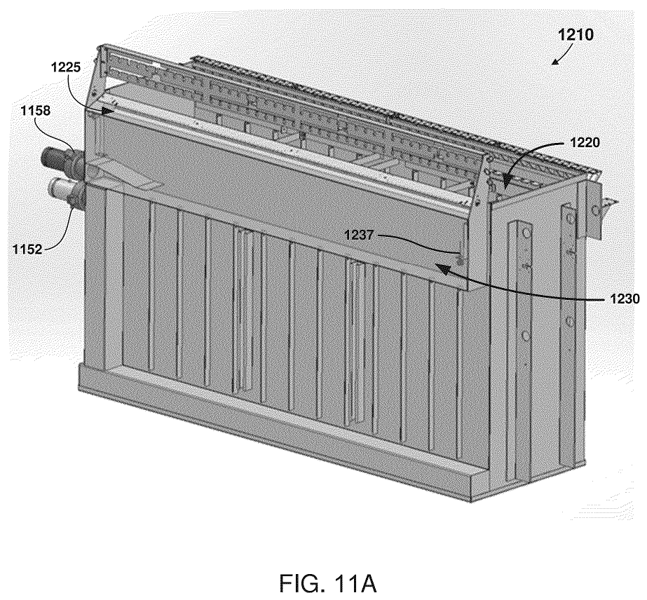

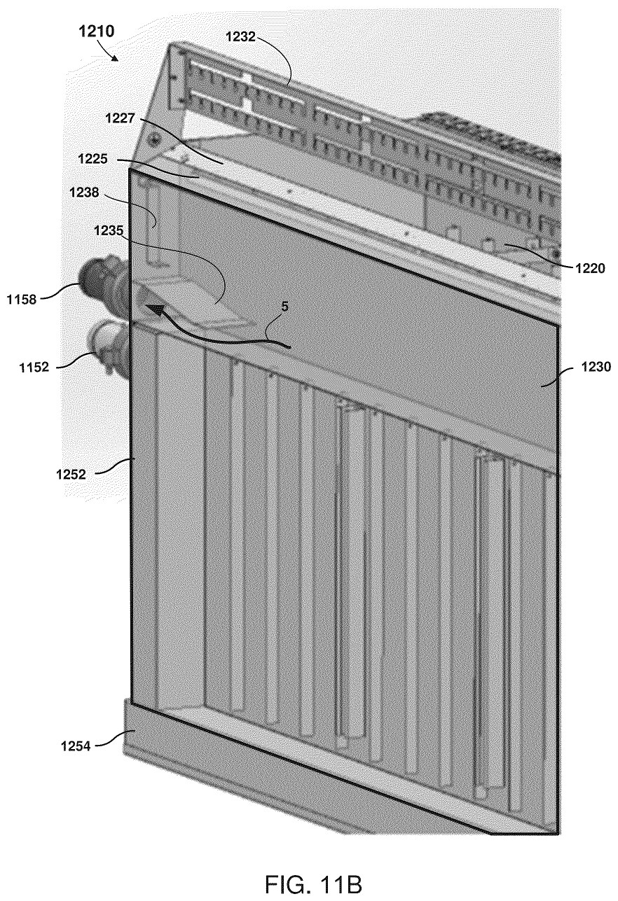

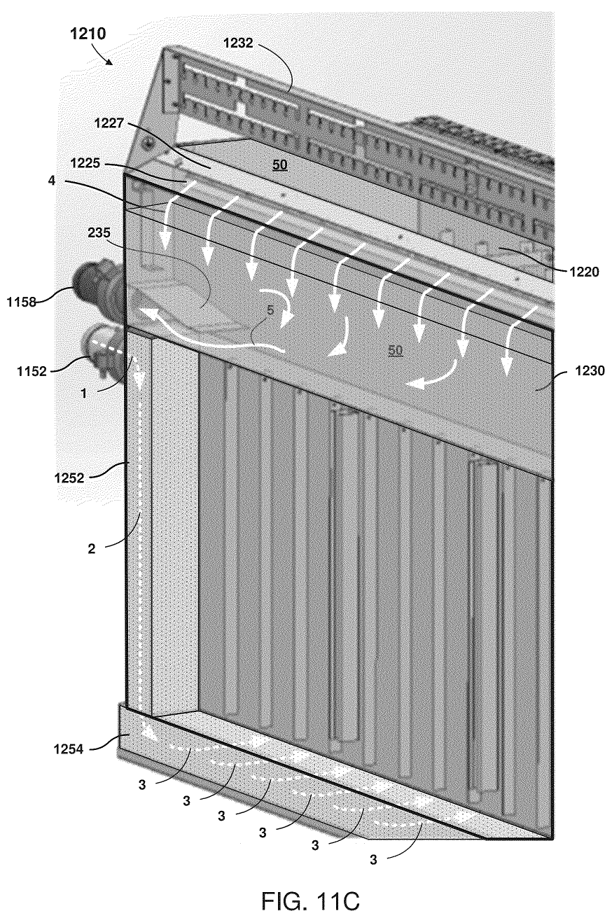

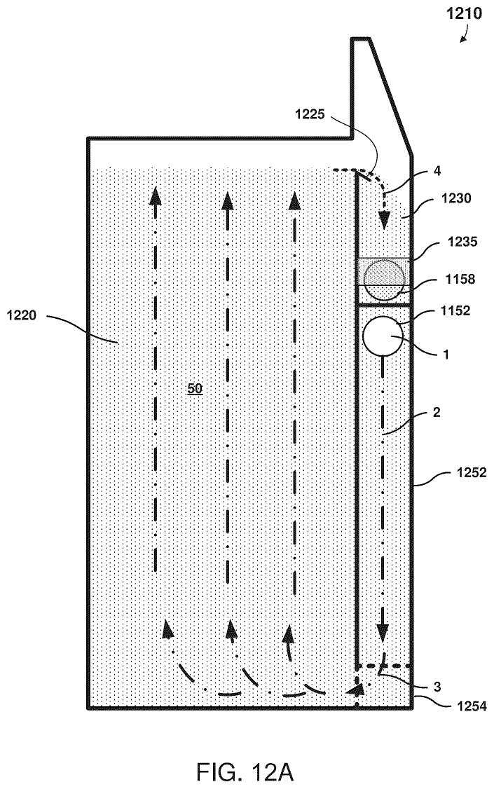

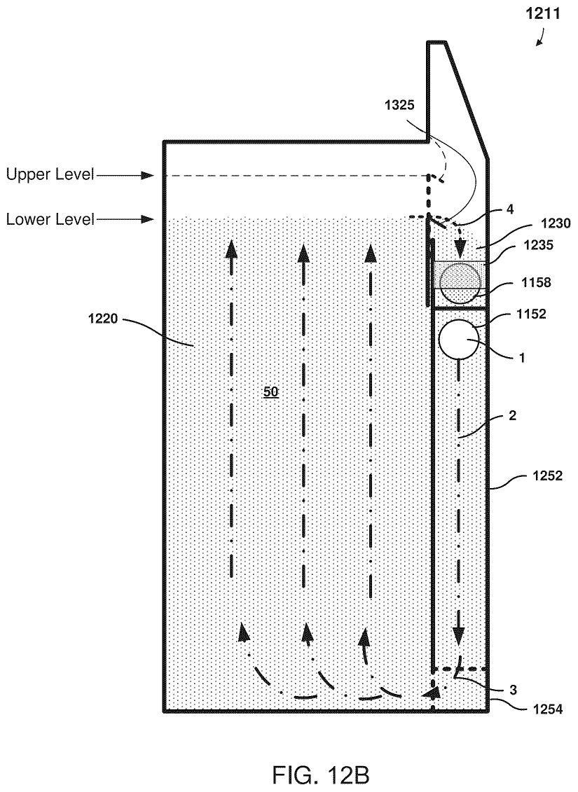

In some embodiments, FIGS. 11A-11C illustrate perspective cut-away views of a rear side of an immersion cooling rack 1210, with front and upper walls removed and an outer rear wall shown as transparent to reveal component and buffer cooling tanks 1230. In some embodiments, FIG. 11A illustrates the entire immersion cooling rack 1210. In some embodiments, FIGS. 11B and 11C are relief views of one side of the immersion cooling rack 1210 that includes inlet and outlet ports. In some embodiments, FIGS. 11A and 11B illustrate the immersion cooling rack 1210 with no coolant fluid, while FIG. 11C illustrates a coolant fluid 50 in various parts of the immersion cooling rack 1210. In some embodiments, FIG. 12A is a side schematic view of the immersion cooling rack 1210 showing an exemplary coolant fluid flow. In some embodiments, the immersion cooling rack 1210 includes a component cooling tank 1220, a buffer cooling tank 1230, and a weir 1225.

In some embodiments, the component cooling tank 1220 is configured to contain at least one electronic component (not shown) at least partially submerged in a volume of coolant fluid pumped into the component cooling tank 1220. In some embodiments, the coolant fluid 50 in the component cooling tank 1220 is configured to prevent electronic components disposed therein from overheating. In some embodiments, the component cooling tank 1220 includes at least one temperature sensor to ensure that the coolant fluid 50 maintains a proper temperature. In some embodiments, a thermal switch is included that is triggered when the temperature of the coolant fluid 50 drops below or rises above a threshold temperature. In some embodiments, triggering of the thermal switch is configured to restrict or increase fluid flow through an adjustable valve in the coolant manifold 1155 or other parts of the coolant fluid flow path. In some embodiments, the component cooling tank 1220 includes a level sensor to monitor the coolant fluid level. In some embodiments, the component cooling tank 1220 includes a water sensor to detect the presence of water that may have spilled or condensed into the coolant fluid 50. In some embodiments, the density of the coolant fluid 50 prevents water from easily mixing into solution with the coolant fluid 50. In some embodiments, detection of water is critical to safe and effective operation, as water may damage the computer components placed in the rack.

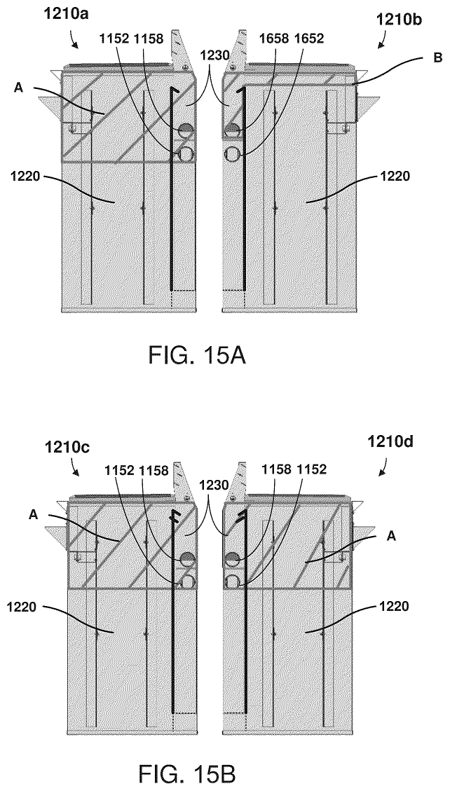

In some embodiments, the buffer cooling tank 1230 is a separate tank from the component cooling tank 1220, as illustrated in FIG. 8 as reservoir 810. In some embodiments, the buffer cooling tank 1230 (810) is configured to receive overflow coolant fluid from the component cooling tank 1220. In some embodiments, the weir 1225 extends along a lower edge of an aperture (see 1226 in FIG. 15) near the top of a barrier (i.e., a wall of the component cooling tank 1220) that separates the component cooling tank 1220 from the buffer cooling tank 1230. In some embodiments, an upper extent of the barrier separating the component cooling tank 1220 from the buffer cooling tank 1230 is lower than the other walls of the component cooling tank 1220. In some embodiments, the weir 1225 is formed as a flat horizontal strip configured to allow excess coolant fluid 50 to spill out from the component cooling tank 1220, over the weir 1225, and into the buffer cooling tank 1230.

In some embodiments, the weir 1225 extends from one side of the component cooling tank 1220 to the other. In some embodiments, the weir 1225 extends across only a portion of the component cooling tank 1220. In some embodiments, more than one weir 1225 is provided, each extending across different portions of the component cooling tank 1220. In some embodiments, a weir 1225 is disposed on any and/or all edges of the component cooling tank 1220 so that the component cooling tank 1220 has a buffer tank around or adjacent to some or all of its perimeter.

In some embodiments, as shown in FIGS. 11B, 12A, and 12B, at a first stage (“1”) of fluid flow into the immersion cooling rack 1210, coolant fluid 50 may enter from the inlet duct 1152 through an inlet port. In some embodiments, the inlet duct 1152 is coupled to an inlet port (e.g., an aperture) that is open to the inside of a hollow vertical column 1252 configured to direct the coolant fluid 50 through a second stage (“2”) of fluid flow toward the bottom of the immersion cooling rack 1210. In some embodiments, from the hollow vertical column 1252, the coolant fluid 50 is directed through a third stage (“3”) of coolant fluid flow through a horizontally extending channel 1254. In some embodiments, an innermost wall of the horizontally extending channel 1254 includes a series of apertures (see inlet ports 1256 in FIG. 14) that extend from the horizontally extending channel 1254 into a lower region of the component cooling tank 1220.

In some embodiments, once the coolant fluid 50 fills the component cooling tank 1220, rather than spilling out of the immersion cooling rack 1210, the weir 1225 may direct overflow of the coolant fluid 50 to a fourth stage (“4”) of coolant fluid flow, which spills over the weir 1225 and into the buffer cooling tank 1230. In some embodiments, the fourth stage (“4”) includes coolant fluid flow through an opening in an upper portion of a wall of the component cooling tank 1220, which extends from the weir 1225 to a weir cover 1227 that is vertically spaced away from the weir 1225. In some embodiments, the weir cover 1227 is removable for service access to the weir 1225. In some embodiments, the opening in the upper portion of the wall of the component cooling tank is covered with a mesh screen or is formed from a wall portion that includes one or more apertures therein.

In some embodiments, the vertical height of the highest part of the weir 1225 is lower than other upper edges of the component cooling tank 1220 that are not intended to retain fluid, to provide a release of overflow coolant fluid 50 into the buffer cooling tank 1230. In some embodiments, once the coolant fluid 50 is in the buffer cooling tank 1230, a fifth stage (“5”) of coolant fluid 50 flow exits the immersion cooling rack 1210 under a whirlpool shield 1235 and out the outlet duct 1158. In some embodiments, a cable management bar 1232 is provided, extending from one end of the immersion cooling rack 1210 to the other, parallel to the weir 1225. In some embodiments, the cable management bar 1232 is configured to attach and/or hold cables that need to run across the assembly or to hold other equipment that needs to remain out of the coolant fluid 50.

In some embodiments, the weir 1225 provides a flow mechanism that maintains a constant level of coolant fluid 50 in the component cooling tank 1220, which is upstream of the weir 1225. In some embodiments, maintaining a constant level of coolant fluid 50 avoids unintentionally exposing the computer components in the component cooling tank 1220 to air, which could occur with variable coolant fluid 50 levels. In some embodiments, the weir 1225 facilitates removal of the hottest coolant fluid 50 from the component cooling tank 1220, since the hottest coolant fluid 50 tends to collect toward the top of the volume of coolant fluid 50 due to the relative density of the hotter coolant fluid 50 compared to the density of the cooler coolant fluid 50. In some embodiments, at least a portion of the weir 1225 is movable substantially vertically or otherwise in order to control coolant fluid 50 levels.

In some embodiments, the area immediately downstream of the weir 1225 but upstream of the outlet duct 1158 acts as a fluid collection zone. In some embodiments, the volume of coolant fluid 50 held back by the weir 1225 may occasionally run low due to imbalances across the multi-rack cooling system 1100. In some embodiments, increasing the coolant fluid 50 flow remedies low coolant fluid 50 levels. In some embodiments, overflow of coolant fluid 50 over the weir 1225 is recirculated back to the coolant distribution unit 1130.

FIG. 12B shows a side schematic view of an immersion cooling rack 1211 showing an exemplary coolant fluid flow. In some embodiments, the immersion cooling rack 1211 includes the component cooling tank 1220, the buffer cooling tank 1230, and an adjustable weir 1325. In some embodiments, when a weir is used for level control of the immersion cooling rack 1211 or multiple racks, the level of the fluid is set by the height of the adjustable weir 1325. In some embodiments, the adjustable weir 1325 is configured to adjust between an upper level and a lower level. In some embodiments, the adjustable weir 1325 is a sliding plate structure that is configured to be raised and lowered. In some embodiments, the adjustable weir 1325 has at least two positions (e.g., upper level and lower level), one or more incremental positions therebetween, or is variably adjustable to any position in between. In some embodiments, a conventional servo-mechanism, motor, or actuator (not shown) is included and configured to raise or lower the adjustable weir 1325 as needed. In some embodiments, the adjustable weir 1325 is formed as a vertical plate that pivots from a pivot point at the lower level, thereby pivoting the uppermost part thereof down into the component cooling tank 1220.

In some embodiments, the buffer cooling tank 1230 is formed as large as possible to allow the greatest level variance. In some embodiments, constraints on the size of the buffer tank are linked to an ideal product size, which is generally as small as possible to minimize floor space usage in valuable data center real estate. In some embodiments, the immersion cooling racks 1210 are positioned back-to-back with inlet and outlet ducts 1152 and 1158 disposed in the same vertical plane.

In some embodiments, the component cooling tank 1220 includes more than one buffer tank disposed on different sides thereof. In some embodiments, one or more weirs 1225 are provided between the component cooling tank 1220 and each side having a buffer tank. In some embodiments, the component cooling tank 1220 is surrounded by buffer tanks, allowing overflow in any direction.

In some embodiments, although it may be advantageous to provide the inlet ducts 1152 at the lowest portion of the immersion cooling rack 1210, design considerations may prevent such inlet duct positioning. In some embodiments, if fittings, gaskets, or components of the inlet ducts 1152 fail, a low inlet port position could result in draining all or most of the coolant fluid 50 in the immersion cooling rack 1210. In some embodiments, it may be advantageous to position the inlet ducts 1152 as high as possible to reduce lost fluid in the event of a leak. In some embodiments, the required fluid containment volume is regulated such that the containment must catch the probable volume of coolant loss. In some embodiments, it is more likely for a fitting connection to leak than a sealed welded vessel. Therefore, in some embodiments, raising the inlet height reduces the probable leak volume and thus reduces the required infrastructure to catch leaks.

In some embodiments, the outlet duct 1158 is positioned as low as possible to maximize variance volume. In some embodiments, variance volume is defined by the difference in fluid volume in the collection zone between maximum and minimum levels. In some embodiments, the maximum fluid level in the collection zone is just below the edge of the weir 1225, and the minimum level is the point at which air begins entering the pump suction.

In some embodiments, the whirlpool shield 1235 is included to ensure that only coolant fluid 50—and not air—is suctioned through the outlet duct 1158. In some embodiments, air intake into the outlet duct 1158 may damage a pump (not shown) that circulates the coolant fluid 50. In some embodiments, the whirlpool shield 1235 is mounted inside the buffer cooling tank 1230 above the outlet 1158. In some embodiments, a first end of the whirlpool shield 1235 is attached to a side wall of the buffer cooling tank 1230, and the whirlpool shield 1235 extends away from the first end toward a second end disposed further from the outlet duct than the first end. In some embodiments, the whirlpool shield 1235 extends downward at an angle (i.e., with a slope) such that the second end is vertically lower than the first end. In some embodiments, the whirlpool shield 1235 is formed to have an L-shape, extending away from the outlet 1158 toward the central part of the buffer cooling tank 1230 and then bending downward at a remote end thereof.

In some embodiments, the whirlpool shield 1235 lowers the minimum fluid level that must be maintained in the buffer cooling tank 1230 before air gets sucked into the outlet duct 1158. In some embodiments, the whirlpool shield 1235 prevents air bubbles caused by coolant fluid 50 flowing over the weir 1225 from entering the outlet duct 1158. In some embodiments, the whirlpool shield 1235 ensures that only fluid is expelled from the bottom of the collection zone. In some embodiments, the whirlpool shield 1235 prevents whirlpool flows inside the buffer cooling tank 1230, particularly near the outlet duct 1158. For example, in some embodiments, with the whirlpool shield 1235 mounted immediately above a 2.5″ diameter outlet duct aperture, the minimum fluid height is lowered by inches, such as ½″, from the bottom of the buffer cooling tank 1230. In some embodiments, the fluid 50 in the buffer cooling tank 1230 is forced under the second end of the whirlpool shield 1235.

In some embodiments, the buffer cooling tank 1230 includes one or more sensors, such as a fluid level sensor 1237 (see FIG. 11A), which detects when the level of the coolant fluid 50 is getting low. In some embodiments, if the coolant fluid level becomes too low, the outlet duct 1158 may start to intake air, which may be undesirable. In some embodiments, the fluid level sensor 1237 is a float sensor that rises and falls with the level of coolant 50. In some embodiments, a temperature sensor is included and mounted inside the buffer cooling tank 1230, such as on a sensor bracket 1238 (see FIG. 11B).

FIG. 14 shows a perspective view of an immersion cooling rack with sidewalls removed to reveal an inner portion of a main cooling tank. FIG. 14 illustrates how the immersion cooling rack 1210 includes a component cooling tank 1220 that includes a series of inlet ports 1256 along a bottom of a sidewall of the component cooling tank 1220, in accordance with some embodiments. In some embodiments, coolant fluid 50 flowing in the horizontally extending channel 1254 flows through the inlet ports 1256 to fill the component cooling tank 1220, eventually flowing over the weir 1225 once the coolant fluid 50 level gets high enough.

In some embodiments, the inlet ports 1256 include nozzles or jets (not shown). In some embodiments, the nozzles or jets are adjustable to direct the orientation of the coolant fluid 50 to flow over a particular location or direction within the component cooling tank 1220. For example, in some embodiments, when a computer component placed in the immersion cooling rack 1210 is known to operate at a higher temperature, multiple inlet ports 1256 may be adjusted to direct more coolant fluid 50 over that hotter computer component. In some embodiments, the flow pressure from each inlet port 1256 is adjustable such that coolant fluid 50 flow may be manipulated due to constructive and/or destructive wave interference of the flow being directed through the inlet ports 1256. In some embodiments, one or more of the inlet ports 1256 may be fully constricted (i.e., closed), thereby forcing the coolant fluid 50 to flow through the remaining open inlet ports 1256 and increasing the pressure at those open ports.

In some embodiments, the immersion cooling rack 1210 includes an outside panel 1111 that is removable to provide access to electronic components, such as those mounted outside the component cooling tanks (e.g., see 1215 in FIG. 11B).

In some embodiments, FIG. 15 is a perspective view of a front side of the immersion cooling rack 1210 with upper components removed to better show the weir 1225 used between the component cooling tank 1220 and the buffer cooling tank 1230. In some embodiments, the immersion cooling rack 1210 includes additional component supports 1270 configured to hold additional electronic components 1510, which remain outside the coolant fluid 50 of either the component cooling tank 1220 or the buffer cooling tank 1230.

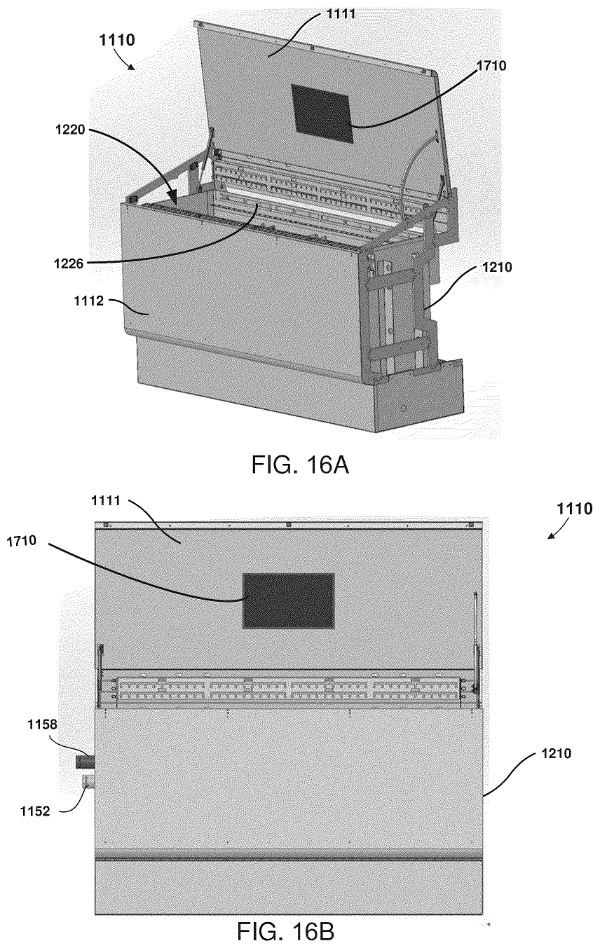

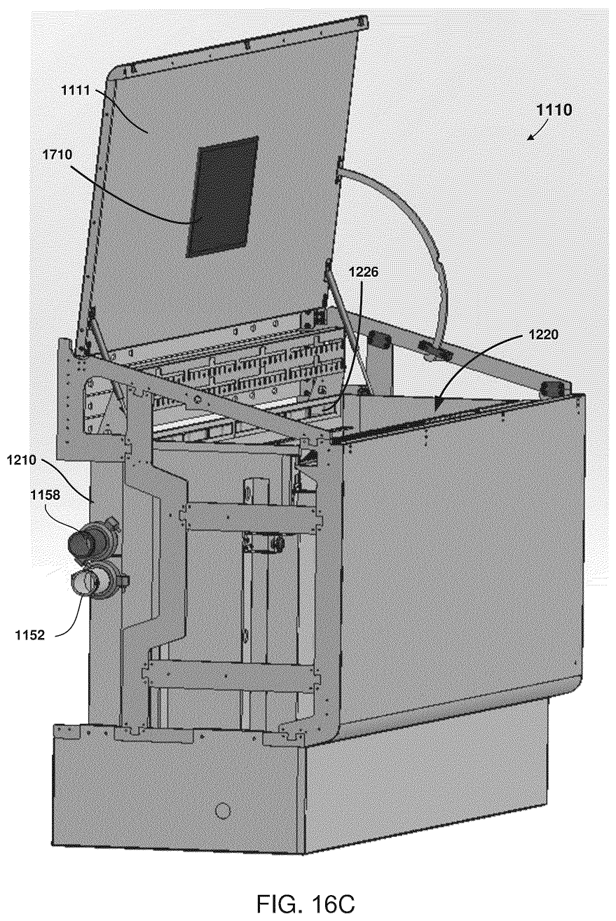

In some embodiments, FIGS. 16A-16B depict side cross-sectional views of adjacent pairs of immersion cooling racks with and without one-way valves. In some embodiments, FIG. 16A illustrates a first pair of immersion cooling racks 1210a and 1210b, one with unregulated two-way valves 1152, 1158 and one with one-way valves 1652, 1658, such as check valves. In contrast, FIG. 16B illustrates a second pair of immersion cooling racks 1210c and 1210d both with ducts 1152, 1158.

In some embodiments, the one-way valves 1652 and 1658 prevent coolant fluid 50 drainage from the immersion cooling racks 1210a and 1210b, particularly during service. In some embodiments, inclusion of one-way valves 1652 and 1658 enables servicing of the immersion cooling racks without loss of coolant fluid 50 and without requiring fluid to be pumped from the immersion cooling racks 1210a and 1210b below the level of the inlet/outlet ducts 1152, 1158 or valves 1652, 1658. In some embodiments, this reduces downtime associated with refilling lost coolant fluid 50 or rebalancing available coolant fluid 50 across all immersion cooling racks.

In some embodiments, check valves used at injection ports prevent drainage. If a leak occurs in piping external to the immersion cooling racks 1210a and 1210b, the amount of fluid drained is reduced significantly. In some embodiments, the first cross-hatched area A represents the amount of coolant fluid 50 that would be lost across immersion cooling racks 1210a and 1210b if a duct or connection thereto leaked or disconnected. In contrast, the second cross-hatched area B shows a far smaller fluid loss in the event of a leak or disconnection. In some embodiments, one-way valves enable integrated containment within a small space, since spill containment capacity can be tailored to the most common spill event-minimized by the presence of the check valve.

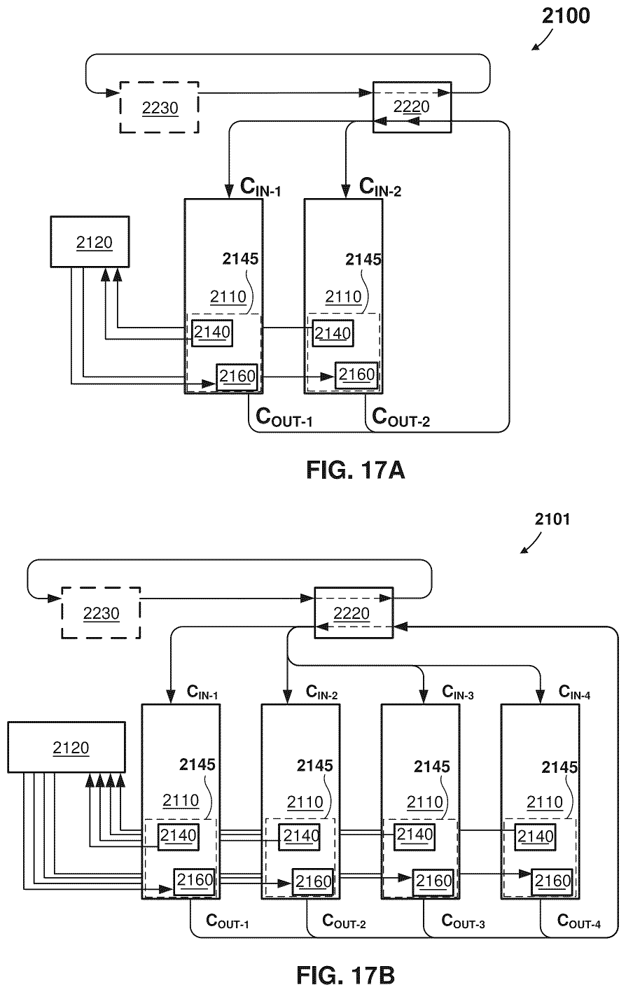

In some embodiments, FIGS. 17A-17C are right side perspective, front, and left side perspective views of an immersion cooling rack assembly with a video monitor. In some embodiments, the immersion cooling rack assembly 1110 includes an upper panel 1111 and an outside panel configured to enclose and/or cover the immersion cooling rack 1210. In some embodiments, the upper panel 1111 is configured to pivot from a closed position (see FIG. 11C) to an open position (see FIGS. 17A-17C). In the open position, the upper panel 1111 allows access to the main cooling tank 1220.

In some embodiments, the upper panel 1111 includes a video monitor 1710. In some embodiments, the video monitor 1710 is configured to provide a visual display of the operating status and/or conditions of the immersion cooling rack assembly. In some embodiments, the video monitor 1710 displays readouts of conditions such as fluid levels and/or temperatures in the main cooling tank 1220. In some embodiments, the video monitor 1710 is coupled to electronic components inside and/or outside the main cooling tanks to display operating status and/or conditions thereof. In some embodiments, the video monitor 1710 assists technicians in maintaining the immersion cooling rack assembly 1110, components therein, and/or the overall multi-rack cooling system 1100.

In some embodiments, the multi-rack cooling system 1100 includes a control unit with one or more processors, memory, and software configured to control the multi-rack cooling system 1100 or parts thereof. In some embodiments, the control unit includes redundant power sources and a programmable logic controller (PLC). In some embodiments, when a preferred power supply for the PLC is lost, a secondary power supply is activated, and/or the PLC performs a restart of the control unit. In some embodiments, when the preferred power supply resumes functioning, the PLC transitions seamlessly back to the preferred supply.

In some embodiments, the control unit (controller) determines when to transition to a secondary coolant circulating system. In some embodiments, the transition is triggered by high coolant temperatures, or failure or errors in the primary coolant circulating system. In some embodiments, the PLC determines whether the secondary coolant circulating system is functioning properly and initiates a return to the primary system when possible, thereby ensuring the best available performance for the coolant circulation system.

In some embodiments, the PLC detects issues in the primary coolant circulating system and switches to the secondary system during normal operation. In some embodiments, issues with the primary pump, variable frequency drive (VFD), or primary power supply are detected using data returned to the PLC from the VFD along with other sensor data from the coolant distribution unit. In some embodiments, a combination of VFD errors, sensor data, or both triggers a transition to the secondary coolant system to maintain optimal functionality. In some embodiments, the VFD is a motor drive used to vary the frequency and/or voltage of power supplied to an AC motor to control speed and torque.

In some embodiments, the control unit determines that a high temperature threshold has been reached (e.g., a thermostat trigger) or that a secondary coolant system should be activated. In some embodiments, a relay is used to make and break contacts, activating a secondary pump and opening a water valve. In some embodiments, this mode of activation resolves error states associated with the water valve control and actuator. In some embodiments, the system provides cross control between two circulating systems-coolant and water-managed under either the primary or secondary control unit.

In some embodiments, multi-rack cooling lighting and/or logo backlighting is used to deliver flash codes, alerts, or warnings to technicians. In some embodiments, the lighting is powered and controlled by the PLC.

In some embodiments, the control unit includes integrated security and access monitoring features. In some embodiments, these features are present in the immersion cooling rack assemblies and/or the coolant distribution unit 1130. In some embodiments, this system provides alerts related to access, lockout/tagout (LOTO) events, technician workflow tracking, and security-level access control. In some embodiments, customer and technician access is restricted to specific units in a collaborative environment.

In some embodiments, a system for controlling coolant levels across a plurality of component cooling tanks configured to share a unified coolant distribution system (e.g., FIGS. 8 and 9) includes a first coolant level regulator of a first component cooling tank, and/or a second coolant level regulator of a second component cooling tank. In some embodiments, the first coolant level regulator may include a first temperature sensor configured to measure a temperature of coolant in a first reservoir, a first coolant release valve configured to regulate the release of coolant from the first reservoir, and/or a first coolant level detector configured to detect a level of the coolant in the first reservoir.

In some embodiments, the second coolant level regulator includes a second temperature sensor configured to measure a temperature of coolant in a second reservoir, a second coolant release valve, and/or a second coolant level detector. In some embodiments, the system is configured to receive temperature measurements from the first and second temperature sensors and/or to signal a target coolant level update configured to adjust a level of the coolant in at least the first reservoir based on one or more temperatures (e.g., average) of the received temperature measurements. In some embodiments, the first coolant release valve may regulate coolant release in response to comparing the detected coolant level in the first reservoir to the target coolant level indicated by the update.

In some embodiments, the first coolant level detector includes a fluid level sensor (e.g., an ultrasonic fluid level sensor). In some embodiments, the first coolant level regulator includes a first coolant level controller configured to receive the signaled target coolant level update and activate the first coolant release valve in response. In some embodiments, the control engine 200 signals the target coolant level update to directly control at least the first coolant release valve. In some embodiments, the target coolant level update is derived from a conversion of the temperature average to a density average of the coolant in the first and second reservoirs.

In some embodiments, the first coolant release valve includes a linear actuator configured to control a state of a coolant gate that regulates coolant release. In some embodiments, the first coolant release valve includes a rotary actuator configured to control a state of a coolant gate that regulates coolant release.

In some embodiments, the processor is further configured to signal the target coolant level update for adjusting the coolant level in at least the second reservoir using the second coolant release valve, based on the temperature average of the received measurements.

In some embodiments, the system further includes third and fourth coolant level regulators associated with a third and fourth component cooling tank, respectively. The third coolant level regulator may include a third temperature sensor, third coolant release valve, and third coolant level detector for a third reservoir. The fourth coolant level regulator may include a fourth temperature sensor, fourth coolant release valve, and fourth coolant level detector for a fourth reservoir. The control engine 200 may receive temperature measurements from the third and fourth temperature sensors and signal the target coolant level update to adjust a level of the coolant in at least one of the third or fourth reservoirs using the respective coolant release valves.

In some embodiments, the first and second reservoirs are configured to hold an overflow of coolant from the respective component cooling tanks and may represent the largest coolant reservoirs of their respective tanks.

In some embodiments, a method of controlling coolant levels across two or more component cooling tanks sharing a unified coolant distribution system includes receiving, at a processor, temperature measurements of coolant in a first and second reservoir. The method further includes receiving a coolant level measurement for the first reservoir and signaling, by the processor, a target coolant level update to respective coolant level regulator components, the update configured to equalize the coolant levels to a target level based on the temperature average and the received level measurement.

In some embodiments, the target coolant level update is derived from a density average computed from the temperature average of the received temperature measurements.

In some embodiments, signaling the target coolant level update includes signaling a first coolant level controller configured to control a first coolant release valve that regulates the release of coolant from the first reservoir and a second coolant level controller configured to control a second coolant release valve that regulates the release of coolant from the first reservoir.

In some embodiments, signaling the target coolant level update includes directly activating at least one of a first coolant release valve that regulates the release of coolant from the first reservoir or a second coolant release valve that regulates the release of coolant from the first reservoir.

Integration of these features into some embodiments of the present disclosure previously described with relation to other figures are now presented below in relation to FIGS. 16-21.

In some embodiments, adjustments to coolant levels in a plurality of cooling tanks that share a volume of circulated coolant, such as those depicted in FIGS. 8 and 9, for example, may be made to one, some, or all of the cooling tanks based on an average temperature of the coolant across the plurality of cooling tanks. In some embodiments, the average temperature may be used to determine a current volume of bulk coolant within the shared volume. In some embodiments, the average temperature may also be used to adjust the amount of coolant maintained in the cooling tanks or within overflow, buffer, and/or outflow reservoirs associated with the tanks. To control coolant levels across the plurality of component cooling tanks, in some embodiments, coolant levels may be adjusted within the tanks themselves and/or within the associated reservoirs. Accordingly, although some embodiments are described as adjusting a volume of a “reservoir,” it should be understood that coolant level regulator components may be implemented within the reservoirs and/or directly within a main component cooling tank. As used herein, the term “reservoir” may refer to a main component cooling tank reservoir, an outflow reservoir, a buffer reservoir, and/or an overflow reservoir, in accordance with some embodiments.

In some embodiments, a cooling circuit (e.g., FIG. 9) supplies coolant to multiple reservoirs. In some embodiments, dynamically regulated valves may be provided at the outlet ports of the reservoirs. In some embodiments, rather than regulating the outlet ports of the manifold or the inlet ports of the reservoirs, the system may dynamically regulate the outlet ports of the reservoirs themselves.

In some embodiments, the coolant level within each of the plurality of reservoirs may be adjusted based on a measured average temperature. In some embodiments, these adjustments may be configured to maintain an equal coolant height across the reservoirs. In some embodiments, maintaining a uniform coolant level across the reservoirs may promote a consistent hydraulic head, which may encourage even outflow of coolant into the suction return line, in accordance with some embodiments.

In some embodiments, coolant height and temperature measurements may be communicated to control engine 200. In some embodiments, the control engine 200 may be configured to evaluate coolant height and temperature data and/or may generate and/or execute instructions to change coolant levels when needed. In some embodiments, control engine 200 may be configured to determine a current average coolant height across the reservoirs and compare it to a target average coolant height. In some embodiments, when a reservoir's coolant height deviates from the target, the system may adjust the coolant flow to bring each reservoir's level to the target average.

The coolant level in a reservoir may reflect both the mass and the temperature of the coolant, since the coolant volume for a given mass may change as a function of its bulk temperature. In some embodiments, a low coolant level at a higher temperature may indicate a more critical condition than the same coolant level at a lower temperature. In some embodiments, in response to detecting a temperature change across the reservoirs, a target average coolant height may be updated accordingly.

In some embodiments, the system may evaluate system parameters to report abnormal conditions and may autonomously adjust coolant levels to a safe state in the event of a communication failure between control elements of multiple reservoir monitoring and control subsystems, such as those depicted in FIG. 9. In some embodiments, individual coolant level controllers associated with each component cooling tank may be configured to operate autonomously, providing a backup or failsafe in the event of a failure of a main system controller. In some embodiments, each reservoir may communicate its respective coolant level and temperature to control engine 200 for determining a current average coolant level. In some embodiments, this average may serve as a control point for calculating a new target average coolant height based on current coolant temperature. In some embodiments, the new target height may be used to adjust coolant levels across the reservoirs accordingly.

In some embodiments, a single-phase cooling distribution system 2100 may be used to remove thermal energy from two or more component cooling tanks (e.g., 2110, 806, 1220, or any combination thereof). In some embodiments, the single-phase cooling distribution system 2100 may include a single-phase cooling distribution unit 2220 configured to circulate coolant between a plurality of component cooling tanks 2110 and a coolant-to-water heat exchanger and/or CDU. In some embodiments, the coolant-to-water heat exchanger may be configured to transfer heat from the coolant to water, and the water may dissipate the absorbed heat in a cooling tower 2230, such as an evaporative cooling tower, dry cooler, chilled water loop, or other cooling infrastructure. In some embodiments, heated coolant may absorb heat from electronic components disposed within the component cooling tanks 2110. In some embodiments, the heated coolant may be circulated from the component cooling tanks 2110 to the coolant-to-water heat exchanger included in the single-phase cooling distribution unit 2220. In some embodiments, cooled coolant may be circulated from the coolant-to-water heat exchanger included in the single-phase cooling distribution unit 2220 back into the component cooling tanks 2110.

In some embodiments, the single-phase cooling distribution unit 2220 may circulate coolant at a coolant input flow rate C_{IN}-1, C_{IN}-2 through each of the component cooling tanks 2110. In some embodiments, the heated coolant may exit the component cooling tanks 2110 as a coolant exit flow rate C_{OUT}-1, C_{OUT}-2 and be recirculated back to the single-phase cooling distribution unit 2220. In some embodiments, the component cooling tanks 2110 may be considered open racks when a liquid-to-air interface is present at atmospheric pressure. In some embodiments, the component cooling tanks 2110 may include lids or covers but are not sealed, allowing for pressure equalization. In some embodiments, the component cooling tanks 2110 may house computing devices that generate heat and are immersed in a dielectric coolant for thermal regulation. Although FIG. 17A shows two component cooling tanks 2110, alternative embodiments may include three or more, in accordance with some embodiments

In some embodiments, the coolant may expand as its temperature increases, resulting in an increase in volume and a corresponding decrease in density. In some embodiments, the opposite may occur when the coolant temperature decreases. In some embodiments, each component cooling tank 2110 may include different types or quantities of electronic components, or operate at varying performance levels, leading to uneven heat generation. In some embodiments, such disparities may cause variations in the coolant volume retained within each component cooling tank 2110. In some embodiments, this may result in differing coolant exit flow rates C_{OUT}-1, C_{OUT}-2 among the tanks.

In some embodiments, the thermal expansion and contraction of the coolant as it fluctuates between minimum and maximum operating temperatures may further complicate coolant level management during fluid displacing equipment removal and/or addition. In some embodiments, reservoirs of the component cooling tanks 2110 may be configured to buffer volumetric changes in dielectric coolant over the normal operating temperature range.

In some embodiments, a system for controlling coolant levels in two or more component cooling tanks 2110 sharing the single-phase cooling distribution system 2100 may include coolant level regulator components 2250 in each of the component cooling tanks 2110 and a controller 2170 communicatively coupled to the coolant level regulator components 2250. In some embodiments, the controller includes at least a portion of control engine 200, and/or receives its instructions from control engine 200.

In some embodiments, the coolant level regulator components 2250 may include a temperature sensor 2150 and a coolant release valve 2140. In some embodiments, each temperature sensor 2150 may be configured to measure a temperature of coolant in a reservoir of a corresponding component cooling tank 2110. In some embodiments, the temperature sensor 2150 may additionally or alternatively be configured to measure air temperature, liquid temperature, or the temperature of solid surfaces. In some embodiments, the temperature sensor 2150 may include a thermistor, RTD, thermocouple, temperature probe, or other temperature-sensing device.

In some embodiments, control valves such as each coolant release valve 2140 may be configured to regulate the release of coolant from a corresponding reservoir. In some embodiments, control engine 200 may be configured to receive temperature measurements from the temperature sensors 2150. In some embodiments, based on the received temperature measurements, the processor may determine a target coolant level for the reservoirs, requiring adjustments to the coolant levels in at least one of the reservoirs via the coolant release valves 2140. In some embodiments, the control engine 200 (e.g., via controller 2170) may signal the target coolant level to one or more of the coolant release valves 2140, such as via a target coolant level update signal. In some embodiments, the target coolant level update may cause one or more of the coolant release valves 2140 to adjust the respective coolant levels.

In some embodiments, each coolant level regulator component 2250 may include a coolant level detector 2160. In some embodiments, the coolant level detector 2160 may be configured to detect a level of coolant in the reservoir, and/or may support a determination by the control engine 200 to adjust coolant release from one or more reservoirs.

In some embodiments, each coolant release valve 2140 may be managed by a coolant level controller 2170, which may be included in the coolant level regulator components 2250. In some embodiments, the control engine 200 may be configured to signal the coolant level controller, which in turn may adjust the corresponding coolant release valve 2140, if necessary.

In some embodiments, multiple immersion cooling rack assemblies 2110 may be used in parallel to reduce the cost per unit of cooling capacity. In some embodiments, four immersion cooling rack assemblies 2110 of approximately 50 U each may be connected to a single pump. In some embodiments, datacenters may use the same IT load in each immersion cooling rack assembly 2110. In some embodiments, colocation facilities may host different load requirements across immersion cooling rack assemblies 2110.

In some embodiments, a single-phase cooling distribution system 2101 may be used to remove thermal energy from four component cooling tanks 2110. In some embodiments, the single-phase cooling distribution system 2101 may include a single-phase cooling distribution unit 2220 configured to circulate coolant between the component cooling tanks 2110 and a heat exchanger, similar to the configuration described with respect to FIG. 17A and/or FIG. 9. In some embodiments, the single-phase cooling distribution unit 2220 may circulate coolant at coolant input flow rates C_{IN}-1, C_{IN}-2, C_{IN}-3, and C_{IN}-4 through each of the four component cooling tanks 2110 to dissipate thermal energy generated by electronic equipment disposed therein. In some embodiments, each of the component cooling tanks 2110 may have a corresponding coolant exit flow rate C_{OUT}-1, C_{OUT}-2, C_{OUT}-3, or C_{OUT}-4. In some embodiments, although FIG. 17B shows four component cooling tanks 2110, alternative embodiments may include two, three, or more than four component cooling tanks 2110. In some embodiments, the single-phase cooling distribution system 2101 may include a system for controlling coolant levels, which may include coolant level regulator components 2250 disposed in each of the component cooling tanks 2110 and a controller 2170 communicatively coupled to the coolant level regulator components 2250 for executing commands from control engine 200. In some embodiments, the coolant level regulator components 2250 may include a temperature sensor 2150 and a coolant release valve 2140, which the controller 2170 may use to determine target coolant level updates for adjusting levels of coolant in at least one of the reservoirs associated with the component cooling tanks 2110.

It should be understood that any reference to any controller can be replaced with “the system” or “the control engine” when defining the metes and bounds of the disclosure, and the system include any combination of the configuration, computer implemented instructions, and/or features, and is not limited to any particular architecture described herein.

FIG. 17A illustrates aspects of the system (the non-limiting configuration here referred to as 2200) for controlling coolant levels in two component cooling tanks (e.g., 2110 in FIG. 16A) sharing a unified coolant distribution platform, in accordance with some embodiments. In some embodiments, the configuration 2200 may include a controller 2120, which is communicatively coupled to coolant level regulator components, such as the temperature sensors 2140-1, 2140-2 and the coolant release valves 2160-1, 2160-2. In some embodiments, the controller 2120 may have a wired and/or wireless connection directly to the coolant level regulator components (e.g., the temperature sensors 2140-1, 2140-2 and the coolant release valves 2160-1, 2160-2) in each reservoir 2130-1, 2130-2. For example, in some embodiments, the controller 2120 may use a communication BUS 2125 configured to communicatively couple the controller 2120 to the coolant level regulator components. The controller 2120 may have a wired and/or wireless connection to a coolant level controller 2150-1, 2150-2, which may be coupled to one or more of the coolant level regulator components, in accordance with some embodiments.

In some embodiments, the reservoirs 2130-1 and 2130-2, which may form part of any configuration described herein, may be configured to hold coolant 2120 therein. In some embodiments, the reservoirs 2130-1 and 2130-2 may be configured to operate as overflow reservoirs, receiving overflow coolant from larger holding tanks, such as those holding electronic components being cooled. In some embodiments, the overflow coolant may flow into each of the reservoirs 2130-1 and 2130-2 through an open top 2132-1, 2132-2 or other aperture at different overflow input flow rates O_{IN}-1, O_{IN}-2. In some embodiments, the reservoirs 2130-1 and 2130-2 may be configured as outflow reservoirs configured to collect coolant prior to it exiting through an outlet duct 2138-1, 2138-2. In some embodiments, the reservoirs 2130-1 and 2130-2 may have extra headspace to buffer volumetric changes in coolant due to temperature changes. In some embodiments, the reservoirs 2130-1 and 2130-2 may potentially have different coolant exit flow rates C_{OUT}-1, C_{OUT}-2. In some embodiments, each reservoir 2130-1 and 2130-2 may instead form the main component holding reservoir of that respective component cooling tank. In this way, the overflow input flow rates O_{IN}-1 and O_{IN}-2 may be equivalent to the coolant input flow rates C_{IN}-1 and C_{IN}-2 described regarding FIG. 16A, in accordance with some embodiments. In some embodiments, additional reservoirs and/or component cooling tanks may be included.

In some embodiments, at room temperature or some other set temperature, an initial coolant height H_{R-init} of the surface level 2125-1, 2125-2 of the coolant 2120 in each reservoir 2130-1, 2130-2 may be known, as well as the corresponding initial temperature Tᵢₙᵢₜ and initial density of the coolant 2120. In some embodiments, the dimensions of each reservoir 2130-1 and 2130-2 may be known, and a horizontal cross-sectional area AR of each reservoir (or an average thereof) may be used in conjunction with the initial coolant height H_{R-init} to determine an initial coolant volume Vᵢₙᵢₜ. In some embodiments, over time, as the electronic components being cooled generate heat and transfer that heat to the coolant, the temperature of the coolant 2120 may increase. In some embodiments, as the temperature of the coolant increases, fluid expansion may cause the coolant levels H_{R-1} and H_{R-2} to rise in each of the reservoirs 2130-1 and 2130-2. In some embodiments, the temperature of the coolant in different reservoirs may vary due to differences in heat generation between component cooling tanks. As a result, the level of coolant rise may vary from tank to tank.

In some embodiments, each reservoir 2130-1 and 2130-2 may include a set of coolant level regulator components configured to control the coolant levels H_{R-1} and H_{R-2}, respectively. In some embodiments, a first reservoir 2130-1 may include first coolant level regulator components, and a second reservoir 2130-2 may include second coolant level regulator components. In some embodiments, the coolant level regulator components may include a temperature sensor 2140 and a coolant release valve 2160-1 or 2160-2. In some embodiments, each temperature sensor 2140-1 and 2140-2 may be configured to measure a temperature of the coolant 2120 in one of the reservoirs 2130-1 or 2130-2. In some embodiments, each coolant release valve 2160-1 and 2160-2 may be configured to regulate the release of coolant from one of the reservoirs through outlet ducts 2138-1 and 2138-2.

In some embodiments, a processor of the controller 2120 may receive a first temperature measurement T₁ from a first temperature sensor 2140-1 of the first reservoir 2130-1 and receive a second temperature measurement T₂ from a second temperature sensor 2140-2 of the second reservoir 2130-2. In some embodiments, using the received temperature measurements T₁ and T₂, the processor may determine a current average reservoir temperature T_{Avg}, such as by computing (T₁+T₂)/2=T_{Avg}. In some embodiments, in systems with more than two reservoirs, temperature measurements from additional reservoirs may be included in the temperature average calculation.

In some embodiments, the coolant 2120 used in the reservoirs 2130-1 and 2130-2 may include a dielectric coolant having known properties such as density p, which varies with temperature. In some embodiments, the initial coolant temperature Tᵢₙᵢₜ may be known, such as an ambient or room temperature. In some embodiments, a correlation between temperature and density may be stored in a lookup table, such as in memory of the controller 2120 or one or more coolant level controllers 2150-1 or 2150-2. In some embodiments, the initial coolant temperature Tᵢₙᵢₜ may correspond to an initial coolant density ρᵢₙᵢₜ. In some embodiments, as coolant temperatures change, the processor of the controller 2120 may use the lookup table to convert an average of the current measured temperatures to an estimated average coolant density ρ_{avg}. For example, an average coolant temperature T_{Avg} may be translated into an average coolant density ρ_{avg}.

In some embodiments, based on the measured temperatures and corresponding densities, the controller 2120 may determine a target coolant height H_{T}, which may represent an optimal coolant level to be maintained across reservoirs 2130-1 and 2130-2. In some embodiments, the processor may use the coolant level regulator components to encourage or ensure that the reservoir coolant levels are adjusted to the target coolant height H_{T}. In some embodiments, the processor may determine the target coolant height H_{T} using the following equation:

$${H}_{T} = {V}_{init} * ( {ρ}_{init} / {ρ}_{a v g} - 1 ) / {A}_{R} + {H}_{R - init} \qquad ( 1 )$$

In this equation, H_{T} represents the target coolant height, Vᵢₙᵢₜ represents the initial coolant volume, ρᵢₙᵢₜ represents the initial coolant density, ρ_{avg} represents an average coolant density derived from T_{Avg}, A_{R} represents the horizontal cross-sectional area of each reservoir, and H_{R-init} represents the initial coolant height. In some embodiments, a lookup table stored in database 108 may alternatively be used to directly map the average measured coolant temperature T_{Avg} to a target coolant height H_{T}.

In some embodiments, once the target coolant height H_{T} is determined, the controller 2120 may initiate operations to control the coolant release valves 2160-1 and 2160-2 for adjusting coolant levels in reservoirs 2130-1 and 2130-2. In some embodiments, the controller 2120 may signal a target coolant level update based on the target coolant height H_{T} to adjust the level of the coolant 2120 in at least one of the reservoirs. In some embodiments, the update may be a control signal transmitted directly to one or both of the coolant release valves 2160-1 and 2160-2. In some embodiments, the coolant release valves may be adjustable and, in turn, may adjust a release of the coolant from the first reservoir 2130-1 and the second reservoir 2130-2. In some embodiments, the control signal may selectively open or close the coolant release valves to increase, maintain, or decrease the coolant levels. In some embodiments, each reservoir may include an independent microcontroller, such as a coolant level controller 2150-1 or 2150-2, that implements proportional-integral-derivative (PID) closed-loop control to adjust coolant exit flow rates C_{OUT}-1 and C_{OUT}-2 for maintaining target coolant levels.

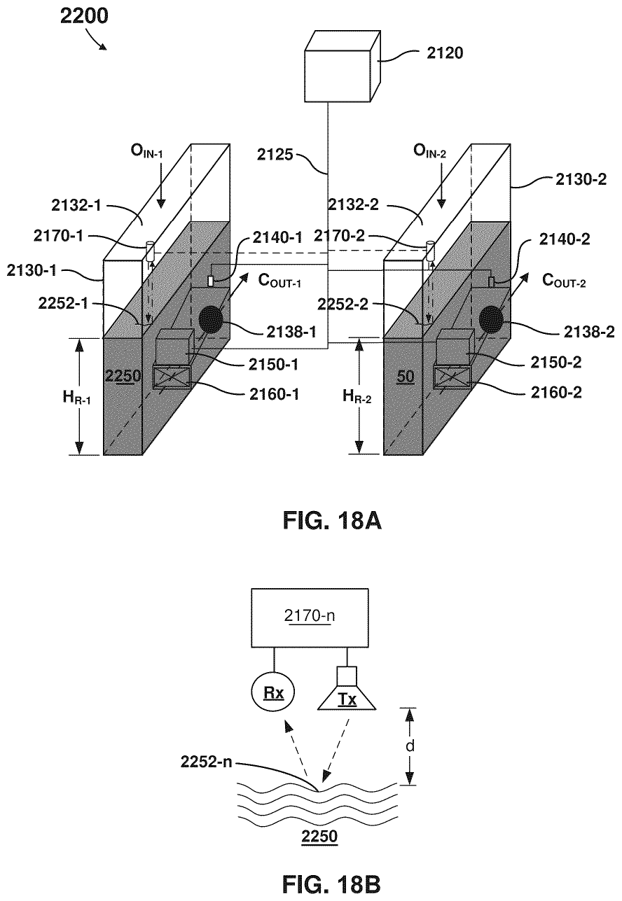

In some embodiments, the coolant level regulator components of system 2200 may include one or more coolant level detectors configured to detect a level of coolant 2120 in the reservoirs 2130-1 and 2130-2. In some embodiments, a first coolant level detector 2170-1 may be disposed in or on the first reservoir 2130-1, and a second coolant level detector 2170-2 may be disposed in or on the second reservoir 2130-2. In some embodiments, one or both coolant level detectors 2170-1 and 2170-2 may include an ultrasonic fluid level meter. FIG. 18B illustrates an ultrasonic coolant level detector 2170-n (i.e., 2170-1 and/or 2170-2) suitable for use with various embodiments. In some embodiments, the ultrasonic meter 2170-n may be a contactless measurement device that transmits (Tx) and receives (Rx) high-frequency acoustic waves to measure a distance d to the surface 2125-n of the coolant 2120.

In some embodiments, the coolant level detectors 2170-1 and 2170-2 may alternatively be capacitance sensors using probes that detect changes in dielectric coolant level. In some embodiments, changes in level may be indicated by variations in capacitance. In some embodiments, the coolant level detectors 2170-1 and 2170-2 may alternatively be pressure sensors or float-type fluid level meters. In some embodiments, float-type sensors may provide less accurate but cost-effective measurements. In some embodiments, other sensor types may be used to additionally or alternatively measure coolant levels H_{R}-1 and H_{R}-2 in the reservoirs 2130-1 and 2130-2.

In some embodiments, the coolant level detectors 2170-1 and 2170-2 may be configured to measure and report the coolant levels H_{R}-1 and H_{R}-2 to the controller 2120 and/or to the respective coolant level controllers 2150-1 and 2150-2. In some embodiments, the controller 2120 and/or the coolant level controllers 2150-1 and 2150-2 may compare the current coolant levels H_{R}-1 and H_{R}-2 to those specified in the target coolant level update (e.g., H_{T}). In instances in which the current coolant level in either reservoir is above the target level H_{T}, the controller 2120 or the corresponding coolant level controller may open or further open the associated coolant release valve 2160-1 or 2160-2 to increase coolant exit flow rate C_{OUT}-1 or C_{OUT}-2.

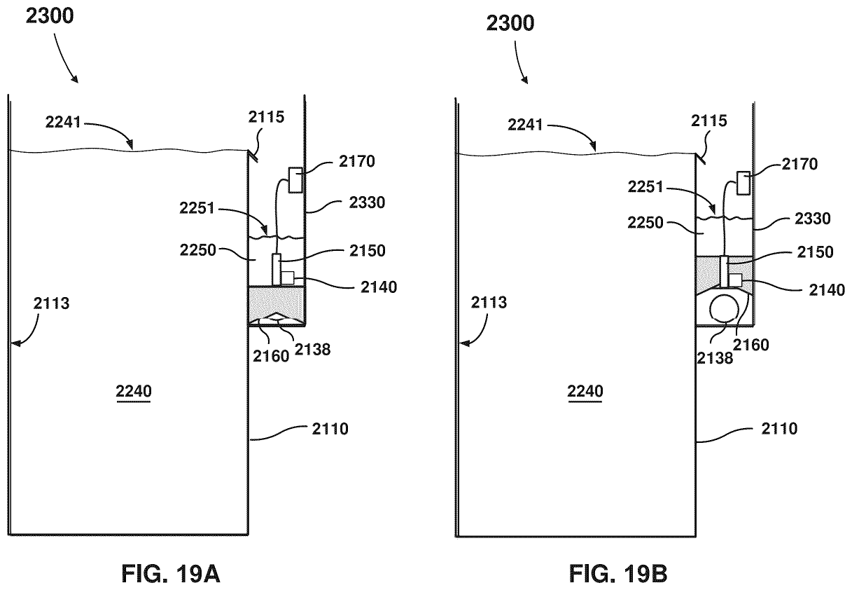

FIGS. 19A and 19B illustrate various aspects of a system 2300 with a component cooling tank 2110 that includes a main component reservoir 2113 and an outflow reservoir 2330 with coolant level regulator components for controlling coolant levels in the outflow reservoir 2330, in accordance with some embodiments. In some embodiments, the outflow reservoir 2330 may include the coolant release valve 2160. In some embodiments, FIG. 19A illustrates the coolant release valve 2160 in a closed position and FIG. 19B illustrates the coolant release valve 2160 in an open position. In some embodiments, the fully closed position of the coolant release valve 2160, as shown in FIG. 19A, may not completely close off or prevent coolant fluid from flowing out the outlet duct 2138 of the outflow reservoir 2330.

In some embodiments, the main component reservoir 2113 may be configured to hold electronic components and may include a weir 2115 that is configured to allow spill-over of coolant 2240 from the main component reservoir 2113 to the outflow reservoir 2330. In some embodiments, when a top surface 2241 of the coolant 2240 reaches the level of the weir 2115, any additional coolant 2240 may spill over the weir 2115 into the outflow reservoir 2330. The outflow reservoir 2330 may be similar to the reservoirs described herein with regard to other configurations formed from some embodiments of the disclosure (e.g., FIGS. 1-21).

In some embodiments, in addition to or as an alternative to the weir 2115, a simple partition wall or siphon ports may be included at the top of a wall between the main component reservoir 2113 and the outflow reservoir 2330. In some embodiments, a partition wall and/or siphon ports may be used instead of or in addition to the weir 2115. In some embodiments, regulated siphon ports may be included anywhere between the main component reservoir 2113 and the outflow reservoir 2330 to transfer excess coolant 2240 between them.

In some embodiments, the outflow reservoir 2330 may include coolant level regulator components, as described above, including the temperature sensor 2140 and the coolant release valve 2160. In some embodiments, the temperature sensor 2140 may be configured to measure the temperature of the coolant 2250 in the outflow reservoir 2330. In some embodiments, the coolant release valve 2160 may be configured to regulate the release of coolant 2250 from the outflow reservoir 2330. In some embodiments, the coolant level regulator components may include the coolant level controller 2150, which may be configured to more directly control the coolant release valve 2160 and to receive measurements from the temperature sensor 2140. In some embodiments, the coolant level regulator components may include the coolant level detector 2170, which may be configured to detect a coolant level of a top surface 2251 of the coolant 2250 in the outflow reservoir 2330.

In some embodiments, the outflow reservoir 2330 may be a separate tank from the component cooling tank 2110 that forms the main component reservoir 2113. In some embodiments, the outflow reservoir 2330 may be configured to receive overflow coolant from the main component reservoir 2113. In some embodiments, the weir 2115 may extend along an upper extent of the barrier separating the component cooling tank 2110 from the outflow reservoir 2330. In some embodiments, the barrier between the two tanks 2110 and 2330 may be lower than the other walls of the component cooling tank 2110. In some embodiments, the weir 2115 may be formed as a flat horizontal strip configured to allow excess coolant 2240 to spill from the component cooling tank 2110, over the weir 2115, and into the outflow reservoir 2330. In some embodiments, the weir 2115 may extend from one side of the component cooling tank 2110 to the other. In other embodiments, the weir 2115 may extend across only a portion of the component cooling tank 2110. In some embodiments, more than one weir 2115 may be provided, each extending across different portions of the component cooling tank 2110. In some embodiments, a weir 2115 may be disposed on any and all edges of the component cooling tank 2110 such that the component cooling tank 2110 has one or more outflow reservoirs 2330 located around some or all of its perimeter.

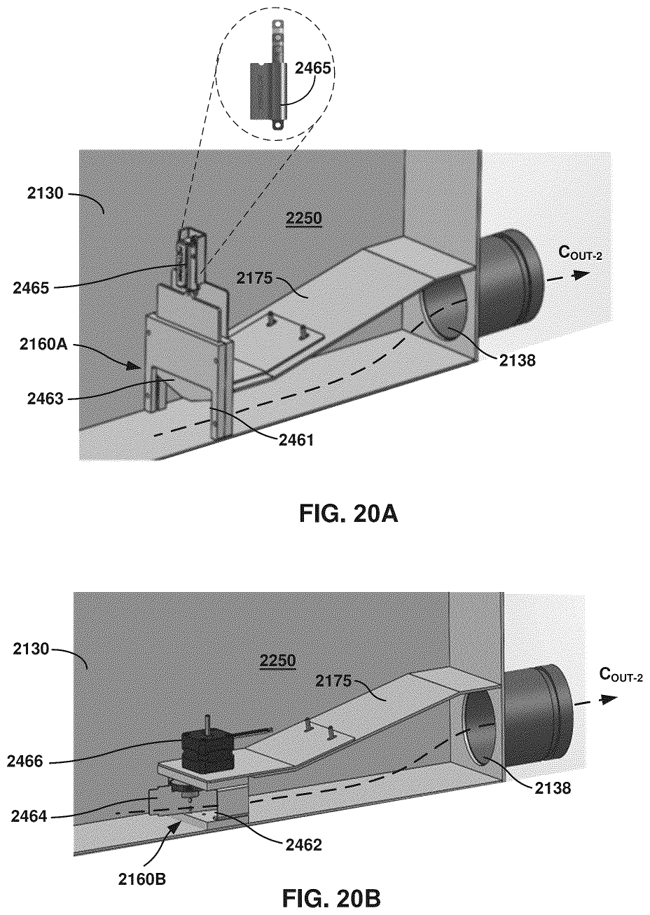

FIGS. 20A and 20B illustrate various aspects of the system including different types of coolant release valves 2160A and 2160B for component cooling tanks, in accordance with some embodiments. In some embodiments, FIG. 20A illustrates a linear coolant release valve 2160A, and FIG. 20B illustrates a rotary coolant release valve 2160B. In some embodiments, the coolant release valves 2160A and 2160B may be disposed at the bottom of a reservoir 2130, with a whirlpool shield 2175 disposed between each of the coolant release valves and their respective outlet duct 2138. In some embodiments, it may be advantageous to position the outlet duct 2138 as low as possible within the reservoir 2130 to maximize variance volume. In some embodiments, variance volume may be defined as the difference in volume of fluid in the collection zone between maximum and minimum levels.

In some embodiments, the whirlpool shield 2175 may ensure that only coolant 2250, and not air, is suctioned through the outlet duct 2138. In some embodiments, the intake or suctioning of air into the outlet duct 2138 may damage a pump used to circulate the coolant 2250. In some embodiments, the whirlpool shield 2175 may be mounted inside the reservoir 2130 above the outlet duct 2138 through which the coolant 2250 exits. In some embodiments, a first end of the whirlpool shield 2175 may be attached to a side wall of the reservoir 2130, such as the wall including the outlet duct 2138. In some embodiments, the whirlpool shield 2175 may extend away from the first end toward a second end disposed further from the outlet duct 2138. In some embodiments, the second end of the whirlpool shield 2175 may be attached to the coolant release valve 2160A or 2160B. In some embodiments, the whirlpool shield 2175 may extend downward at an angle such that the second end is vertically lower than the first end. In some embodiments, the whirlpool shield 2175 may alternatively be formed with an L-shape, extending away from the outlet duct 2138 toward a central part of the reservoir 2130 and then bending downward at a remote end. In some embodiments, the whirlpool shield 2175 may lower the minimum coolant level required in the reservoir 2130 before air enters the outlet duct 2138. In some embodiments, the whirlpool shield 2175 may prevent air bubbles caused by coolant 2240 flowing over a weir 2115 into the reservoir 2130 from entering the outlet duct 2138. In some embodiments, the whirlpool shield 2175 may ensure that only fluid is expelled from the bottom of the collection zone and may suppress whirlpool flow next to the outlet duct 2138. In some embodiments, for example, when the whirlpool shield 2175 is mounted above a 2.5-inch diameter outlet aperture, the minimum fluid height may be lowered by several inches, such as ½ inch from the bottom of the reservoir 2130. In some embodiments, the coolant 2250 in the reservoir 2130 may be forced under the second end of the whirlpool shield 2175.

In FIG. 20A, in some embodiments, the linear coolant release valve 2160A may include a valve frame 2461 and a linear slide door 2463 configured to move up and down to open and close the valve and thereby adjust the size of the exit opening leading to the outlet duct 2138 beneath the whirlpool shield 2175. In some embodiments, actuation of the linear slide door 2463 may be controlled by a (linear) servo 2465, which may in turn be controlled by control engine 200, such as via controller 2120 and/or 2150. In some embodiments, a lower edge of the linear slide door 2463 may be non-uniform or intentionally gapped to allow a small amount of coolant 2250 to leak through the valve 2160A in the fully closed position, maintaining a minimal exit flow rate such as C_{OUT}-2.

In FIG. 20B, in some embodiments, the rotary coolant release valve 2160B may include a valve frame 2462 and a rotary pivot door 2464 configured to rotate about a vertical axis to open and close the valve, thus adjusting the size of the exit opening leading to the outlet duct 2138 beneath the whirlpool shield 2175. In some embodiments, the rotary pivot door 2464 may alternatively pivot about a horizontal axis, such as one perpendicular to the exit flow C_{OUT}-2. In some embodiments, the rotating motion of the rotary pivot door 2464 may be actuated by a rotary servo 2466, which may be controlled by controller 2120 and/or 2150. In some embodiments, the rotary pivot door 2464 may not fully close off the valve opening, leaving a small gap that allows a limited coolant 2250 flow to leak through valve 2160B even in the closed position.

In some embodiments, the coolant release valves 2160A and 2160B illustrated in FIGS. 20A and 20B may be disposed inside a portion of the reservoir 2130. In other embodiments, the coolant release valves 2160A and 2160B may be located outside the reservoir 2130, such as between the reservoir and a shared manifold.

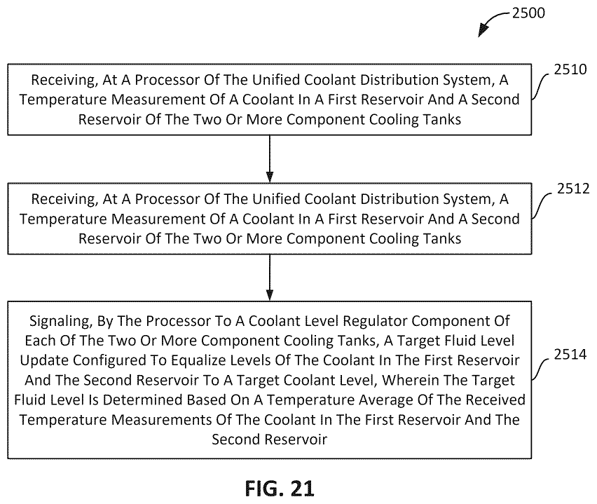

FIG. 21 illustrates various aspects of a method 2500 for controlling coolant levels in two or more component cooling tanks sharing a unified coolant distribution system, in accordance with some embodiments. In some embodiments, and with reference to FIGS. 1-20, control engine 200, e.g., via a controller (e.g., 2120, 2150, 2150-1, 2150-2) of the unified coolant distribution system and/or another processor associated therewith, can execute any combination of instructions described herein. The operations and/or instructions described with relation to FIG. 21 can form part of the instructions described in FIGS. 3 and 4, for example, or any other instructions described herein, in accordance with some embodiments.

In some embodiments, in operation 2510, the control engine 200, by the execution of instructions via one or more processors, may receive a temperature measurement of coolant in a first reservoir (e.g., 2130-1) and a second reservoir (e.g., 2130-2) of the two or more component cooling tanks 2110. In some embodiments, the temperature measurements received from the first and second reservoirs may not be the same. In some embodiments, the received temperature measurements may be used to anticipate fluid level changes, which may be a function of temperature variation from a known reference fluid level as well as component addition and/or removal.

In some embodiments, following the receipt of temperature measurements in operation 2510, the control engine 200 may receive a coolant level measurement of the coolant in the first and/or second reservoir in operation 2512. In some embodiments, the control engine 200 may receive the coolant level measurement(s) prior to the temperature measurement(s). In some embodiments, the received coolant level measurement(s) may be used by the control engine 200 to determine a target coolant level update. In some embodiments, the received level data may serve to confirm a coolant level inferred from the measured temperature. In some embodiments, the system is configured to use a current ambient temperature in conjunction with a fluid displacing component's thermal mass to determine a temperature drop from an inserted component.

In some embodiments, in operation 2514, the control engine 200 may signal to a coolant level regulator component 2250 of each of the two or more component cooling tanks 2110 a target coolant level update during an add/delete state. In some embodiments, the target coolant level update may be configured to equalize the levels of coolant in the first and second reservoirs to a target coolant level after component removal/insertion. In some embodiments, the target coolant level may be determined based on a temperature average of the received temperature measurements, the thermal mass of a component, ambient temperature, and/or flowrate change requirements. In some embodiments, signaling the target coolant level update includes directly activating at least one of a first coolant release valve (e.g., 2160, 2160-1) that regulates the release of coolant from the first reservoir, or a second coolant release valve (e.g., 2160, 2160-2) that regulates the release of coolant from the second reservoir. In some embodiments, signaling the target coolant level update may include using updated temperature measurements (e.g., from temperature sensors 2140, 2140-1, 2140-2) and/or updated coolant level measurements (e.g., from coolant level detectors 2170, 2170-1, 2170-2) to determine whether coolant should be released from either or both reservoirs to achieve the target coolant level during an add/remove state.

In some embodiments, the target coolant level update signaled by the processor may be determined by converting the temperature average of the received temperature measurements into a density average of the coolant in the first and second reservoirs. In some embodiments, signaling the target coolant level update may include control engine 200 signaling a first coolant level controller (e.g., 2150, 2150-1) configured to control a first coolant release valve that regulates the release of coolant 2240 or 2250 from the first reservoir, and also signaling a second coolant level controller (e.g., 2150, 2150-2) configured to control a second coolant release valve (e.g., 2160, 2160-2) that regulates the release of coolant from the second reservoir. In some embodiments, the first coolant level controller may use the received target coolant level update in conjunction with updated temperature measurements (e.g., from temperature sensor 2140 or 2140-1) and/or coolant level measurements (e.g., from coolant level detector 2170 or 2170-1) from control engine 200 to determine whether to release coolant from the first reservoir. Similarly, the second coolant level controller may use the received target coolant level update from control engine 200 in conjunction with updated temperature measurements (e.g., from temperature sensor 2140-2) and/or coolant level measurements (e.g., from coolant level detector 2170-2) to determine whether to release coolant from the second reservoir. In some embodiments, signaling the target coolant level update includes directly activating at least one of a first coolant release valve that regulates the release of coolant from the first reservoir or a second coolant release valve that regulates the release of coolant from the first reservoir.

In some embodiments, the operations of the method 2500 may be performed continuously or periodically to adjust, maintain, and/or control coolant levels in the two or more component cooling tanks 2110 sharing the unified coolant distribution system.

While various configurations associated with different figures are presented herein to aid in describing features of the system, it is understood that any features of the system presented in some embodiments of this disclosure are combinable with any other features in accordance with some embodiments, such that any portion of the system description may be combined with any other portion of the system when defining the metes and bounds of protection sought. For example, reservoir control and/or structures described in relation to FIGS. 16-21 can be integrated with, and/or exchanged with portions of, the control configurations described in FIGS. 1-9 and/or the structures described in FIGS. 10-15, as non-limiting examples.

As used herein, the term “engine” identifies at least one software component and/or a combination of at least one software component and at least one hardware component which are designed/programmed/configured to manage/control other software and/or hardware components (such as the libraries, software development kits (SDKs), objects, and the like).

Examples of hardware elements may include processors, microprocessors, circuits, circuit elements (e.g., transistors, resistors, capacitors, inductors, and so forth), integrated circuits, application specific integrated circuits (ASIC), programmable logic devices (PLD), digital signal processors (DSP), field programmable gate array (FPGA), logic gates, registers, semiconductor device, chips, microchips, chip sets, and so forth. In some embodiments, the one or more processors may be implemented as a Complex Instruction Set Computer (CISC) or Reduced Instruction Set Computer (RISC) processors; x86 instruction set compatible processors, multi-core, or any other microprocessor or central processing unit (CPU). In various implementations, the one or more processors may be dual-core processor(s), dual-core mobile processor(s), and so forth.

Computer-related systems, computer systems, and systems, as used herein, include any combination of hardware and software. Examples of software may include software components, programs, applications, operating system software, middleware, firmware, software modules, routines, subroutines, functions, methods, procedures, software interfaces, application program interfaces (API), instruction sets, computer code, computer code segments, words, values, symbols, or any combination thereof. Determining whether some embodiments are implemented using hardware elements and/or software elements may vary in accordance with any number of factors, such as desired computational rate, power levels, heat tolerances, processing cycle budget, input data rates, output data rates, memory resources, data bus speeds and other design or performance constraints.

For the purposes of this disclosure a module is a software, hardware, or firmware (or combinations thereof) system, process or functionality, or component thereof, that performs or facilitates the processes, features, and/or functions described herein (with or without human interaction or augmentation). A module can include sub-modules. Software components of a module may be stored on a computer readable medium for execution by a processor. Modules may be integral to one or more servers or be loaded and executed by one or more servers. One or more modules may be grouped into an engine or an application.

One or more aspects of some embodiments may be implemented by representative instructions stored on a machine-readable medium which represents various logic within the processor, which when read by a machine causes the machine to execute logic to perform the techniques described herein. Such representations, known as “IP cores,” may be stored on a tangible, machine readable medium and supplied to various customers or manufacturing facilities to load into the fabrication machines that make the logic or processor. In some embodiments, instructions may be implemented using any appropriate hardware and/or computing software languages (e.g., C++, Objective-C, Swift, Java, JavaScript, Python, Perl, QT, and the like).

For example, exemplary software specifically programmed in accordance with one or more principles of the present disclosure may be downloadable from a network, for example, a website, as a stand-alone product or as an add-in package for installation in an existing software application. For example, exemplary software specifically programmed in accordance with one or more principles of the present disclosure may also be available as a client-server software application, or as a web-enabled software application. For example, exemplary software specifically programmed in accordance with one or more principles of the present disclosure may also be embodied as a software package installed on a hardware device.

For the purposes of this disclosure the term “user,” “subscriber” “provider,” “supplier,” or “customer” should be understood to refer to a user of an application or applications as described herein and/or a consumer of data supplied by a data provider. By way of example, and not limitation, the term “user” or “subscriber” can refer to a person who receives data provided by the data or service provider over the Internet in a browser session or can refer to an automated software application which receives the data and stores or processes the data. Those skilled in the art will recognize that the methods and systems of the present disclosure may be implemented in many manners and as such are not to be limited by some embodiments and examples. In other words, functional elements being performed by single or multiple components, in various combinations of hardware and software or firmware, and individual functions, may be distributed among software applications at either the client level or server level or both. In this regard, any number of the features of some embodiments described herein may be combined into single or multiple configurations, and some embodiments having fewer than, or more than, all of the features described herein are possible.

The disclosure describes the specifics of how a machine including one or more computers comprising one or more processors and one or more non-transitory computer readable media implement the system and its improvements over the prior art. The instructions executed by the machine cannot be performed in the human mind or derived by a human using a pen and paper but instead includes the machine converting input data to useful output data. Moreover, the claims presented herein do not attempt to tie-up a judicial exception with known conventional steps implemented by a general-purpose computer; nor do they attempt to tie-up a judicial exception by simply linking it to a technological field. Indeed, the systems and methods described herein were unknown and/or not present in the public domain at the time of filing, and they provide technologic improvements and advantages not known in the prior art. Furthermore, the system includes unconventional steps that confine the claim to a useful application.

It is understood that the system is not limited in its application to the details of construction and the arrangement of components set forth in the previous description or illustrated in the drawings. The system and methods disclosed herein fall within the scope of numerous embodiments. The previous discussion is presented to enable a person skilled in the art to make and use embodiments of the system. Any portion of the structures and/or principles included in some embodiments can be applied to any and/or all embodiments: it is understood that features from some embodiments presented herein are combinable with other features according to some other embodiments. Thus, some embodiments of the system are not intended to be limited to what is illustrated but are to be accorded the widest scope consistent with all principles and features disclosed herein.

Some embodiments of the system are presented with specific values and/or setpoints. These values and setpoints are not intended to be limiting and are merely examples of a higher configuration versus a lower configuration and are intended as an aid for those of ordinary skill to make and use the system.

Any text in the drawings is part of the system's disclosure and is understood to be readily incorporable into any description of the metes and bounds of the system. Any functional language in the drawings is a reference to the system being configured to perform the recited function, and structures shown or described in the drawings are to be considered as the system comprising the structures recited therein. Any figure depicting a content for display on a graphical user interface is a disclosure of the system configured to generate the graphical user interface and configured to display the contents of the graphical user interface. It is understood that defining the metes and bounds of the system using a description of images in the drawing does not need a corresponding text description in the written specification to fall with the scope of the disclosure.

It is understood that the phraseology and terminology used herein is to aid those of ordinary skill realize the scope of the system and should not be regarded as limiting. The use of “including,” “comprising,” or “having” and variations thereof herein is meant to encompass the items listed thereafter and equivalents thereof as well as additional items. Unless specified or limited otherwise, the terms “mounted,” “connected,” “supported,” and “coupled” and variations thereof are used broadly and encompass both direct and indirect mountings, connections, supports, and couplings. Further, “connected” and “coupled” are not restricted to physical or mechanical connections or couplings.

Furthermore, acting as Applicant's own lexicographer, Applicant imparts the explicit meaning and/or disavow of claim scope to the following terms:

Applicant defines any use of “and/or” such as, for example, “A and/or B,” or “at least one of A and/or B” to mean element A alone, element B alone, or elements A and B together. In addition, a recitation of “at least one of A, B, and C,” a recitation of “at least one of A, B, or C,” or a recitation of “at least one of A, B, or C or any combination thereof” are each defined to mean element A alone, element B alone, element C alone, or any combination of elements A, B and C, such as AB, AC, BC, or ABC, for example.

“Substantially” and “approximately” when used in conjunction with a value encompass a difference of 5% or less of the same unit and/or scale of that being measured.

“Simultaneously” as used herein includes lag and/or latency times associated with a computer, such as processors and/or networks described herein attempting to process multiple types of data at the same time. “Simultaneously” also includes the time it takes for digital signals to transfer from one physical location to another, be it over a wireless and/or wired network, and/or within processor circuitry.

As used herein, “can” or “may” or derivations thereof (e.g., the computer can execute instructions X) are used for descriptive purposes only and is understood to be synonymous and/or interchangeable with “configured to” (e.g., the computer is configured to execute instructions X) when defining the metes and bounds of the system. The phrase “configured to” also denotes the step of configuring a structure or computer to execute a function according to some embodiments.

In addition, the term “configured to” means that the limitations recited in the specification and/or the claims must be arranged in such a way to perform the recited function: “configured to” excludes structures in the art that are “capable of” being modified to perform the recited function but the disclosures associated with the art have no explicit teachings to do so. For example, a recitation of a “container configured to receive a fluid from structure X at an upper portion and deliver fluid from a lower portion to structure Y” is limited to systems where structure X, structure Y, and the container are all disclosed as arranged to perform the recited function. The recitation “configured to” excludes elements that may be “capable of” performing the recited function simply by virtue of their construction but associated disclosures (or lack thereof) provide no teachings to make such a modification to meet the functional limitations between all structures recited. Another example is “a computer system configured to or programmed to execute a series of instructions X, Y, and Z.” In this example, the instructions must be present on a non-transitory computer readable medium such that the computer system is “configured to” and/or “programmed to” execute the recited instructions: “configure to” and/or “programmed to” excludes art teaching computer systems with non-transitory computer readable media merely “capable of” having the recited instructions stored thereon but have no teachings of the instructions X, Y, and Z stored thereon. The recitation “configured to” can also be interpreted as synonymous with operatively connected when used in conjunction with physical structures.

It is understood that the phraseology and terminology used herein is for description and should not be regarded as limiting. The use of “including,” “comprising,” or “having” and variations thereof herein is meant to encompass the items listed thereafter and equivalents thereof as well as additional items. Unless specified or limited otherwise, the terms “mounted,” “connected,” “supported,” and “coupled” and variations thereof are used broadly and encompass both direct and indirect mountings, connections, supports, and couplings. Further, “connected” and “coupled” are not restricted to physical or mechanical connections or couplings.

The previous detailed description is to be read with reference to the figures, in which like elements in different figures have like reference numerals. The figures, which are not necessarily to scale, depict some embodiments and are not intended to limit the scope of embodiments of the system.

Any of the operations described herein that form part of the system are useful machine operations. The system also relates to a device or an apparatus for performing these operations. All flowcharts presented herein represent computer implemented steps and/or are visual representations of algorithms implemented by the system. The apparatus can be specially constructed for the required purpose, such as a special purpose computer. When defined as a special purpose computer, the computer can also perform other processing, program execution or routines that are not part of the special purpose, while still being capable of operating for the special purpose. Alternatively, the operations can be processed by a general-purpose computer selectively activated or configured by one or more computer programs stored in the computer memory, cache, or obtained over a network. When data is obtained over a network the data can be processed by other computers on the network, e.g., a cloud of computing resources.

The embodiments of the system can also be defined as a machine that transforms data from one state to another state. The data can represent an article, that can be represented as an electronic signal and electronically manipulate data. The transformed data can, in some cases, be visually depicted on a display, representing the physical object that results from the transformation of data. The transformed data can be saved to storage generally, or in particular formats that enable the construction or depiction of a physical and tangible object. In some embodiments, the manipulation can be performed by a processor. In such an example, the processor thus transforms the data from one thing to another. Still further, some embodiments include methods can be processed by one or more machines or processors that can be connected over a network. Each machine can transform data from one state or thing to another, and can also process data, save data to storage, transmit data over a network, display the result, or communicate the result to another machine. Computer-readable storage media, as used herein, refers to physical or tangible storage (as opposed to signals) and includes without limitation volatile and non-volatile, removable, and non-removable storage media implemented in any method or technology for the tangible storage of information such as computer-readable instructions, data structures, program modules or other data.

Although method operations are presented in a specific order according to some embodiments, the execution of those steps do not necessarily occur in the order listed unless explicitly specified. Also, other housekeeping operations can be performed in between operations, operations can be adjusted so that they occur at slightly different times, and/or operations can be distributed in a system which allows the occurrence of the processing operations at various intervals associated with the processing, as long as the processing of the overlay operations are performed in the desired way and result in the desired system output.

It will be appreciated by those skilled in the art that while the system has been described above in connection with particular embodiments and examples, the system is not necessarily so limited, and that numerous other embodiments, examples, uses, modifications and departures from the embodiments, examples and uses are intended to be encompassed by the claims attached hereto. The entire disclosure of each patent and publication cited herein is incorporated by reference, as if each such patent or publication were individually incorporated by reference herein. Various features and advantages of the system are set forth in the following claims.

What is claimed is:

1. A system comprising:
one or more computers comprising one or more processors and one or more non-transitory computer readable media, the one or more non-transitory computer readable media comprising program instructions stored thereon that when executed cause the one or more computers to:
receive, by the one or more processors, level data from one or more sensors associated with an immersion cooling rack;
determine, by the one or more processors, an expected change in a level of a cooling tank associated with the immersion cooling rack as a result of one or more fluid displacing components being removed from the cooling tank; and
execute, by the one or more processors, a fluid transfer operation configured to prevent the level in the cooling tank from dropping below a pre-determined setpoint.

2. The system of claim 1,
wherein the expected change in the level of the cooling tank is at least partially determined using a tank volume of fluid in the cooling tank and a component volume of the one or more fluid displacing components.

3. The system of claim 2,
wherein the expected change in the level of the cooling tank is at least partially determined by using a temperature of the cooling tank.

4. The system of claim 3,
wherein the expected change in the level of the cooling tank is at least partially determined by determining a change in cooling tank temperature caused by a removal of the one or more fluid displacing components.

5. The system of claim 2,
wherein the fluid transfer operation includes automatic control of one or more valves to deliver additional fluid to the cooling tank.

6. The system of claim 5,
wherein the additional fluid is configured to prevent one or more remaining components from becoming exposed to atmosphere.

7. The system of claim 2,
wherein the fluid transfer operation includes transferring liquid from one or more other immersion cooling racks to the cooling tank.

8. The system of claim 2,
wherein the fluid transfer operation includes transferring liquid from a reservoir to the cooling tank.

9. The system of claim 2,
wherein the fluid transfer operation includes transferring liquid to the cooling tank from a fluid circuit; and
wherein the fluid circuit includes a plurality of immersion cooling racks and a plurality of coolant distribution units.

10. A system comprising:
one or more computers comprising one or more processors and one or more non-transitory computer readable media, the one or more non-transitory computer readable media comprising program instructions stored thereon that when executed cause the one or more computers to:
receive, by the one or more processors, level data from one or more sensors associated with an immersion cooling rack;
determine, by the one or more processors, an expected change in a level of a cooling tank associated with the immersion cooling rack as a result of one or more fluid displacing components being added to the cooling tank; and
execute, by the one or more processors, a fluid transfer operation configured to prevent the level in the cooling tank from rising above a pre-determined setpoint.

11. The system of claim 10,
wherein the expected change in the level of the cooling tank is at least partially determined using a tank volume of fluid in the cooling tank and a component volume of the one or more fluid displacing components.

12. The system of claim 11,
wherein the expected change in the level of the cooling tank is at least partially determined by using a temperature of the cooling tank.

13. The system of claim 12,
wherein the expected change in the level of the cooling tank is at least partially determined by determining a change in cooling tank temperature caused by an addition of the one or more fluid displacing components.

14. The system of claim 11,
wherein the fluid transfer operation includes automatic control of one or more valves to remove fluid from the cooling tank.

15. The system of claim 14,
wherein the removed fluid is configured to prevent the cooling tank from overflowing.

16. The system of claim 11,
wherein the fluid transfer operation includes transferring liquid from the cooling tank to one or more other immersion cooling racks.

17. The system of claim 11,
wherein the fluid transfer operation includes transferring liquid from the cooling tank to a reservoir.

18. The system of claim 11,
wherein the fluid transfer operation includes transferring liquid from the cooling tank to a fluid circuit; and
wherein the fluid circuit includes a plurality of immersion cooling racks and a plurality of coolant distribution units.
